(19) United States
(12) Patent Application Publication
(10) Pub. No.: US 2016/0020155 A1
(43) Pub. Date: Jan. 21, 2016

(54) LIGHT SOURCE TESTING APPARATUS, TESTING METHOD OF LIGHTING SOURCE AND MANUFACTURING METHOD OF LIGHT-EMITTING DEVICE PACKAGE, LIGHT EMITTING MODULE, AND ILLUMINATION APPARATUS USING THE SAME

(71) Applicants: Soo Seong Kim, Hwaseong-si (KR); Sung Hyun Moon, Yongin-si (KR)

(72) Inventors: Soo Seong Kim, Hwaseong-si (KR); Sung Hyun Moon, Yongin-si (KR)

(21) Appl. No.: 14/573,210

(22) Filed: Dec. 17, 2014

(30) Foreign Application Priority Data
Jul. 16, 2014 (KR) 10-2014-0089793

(51) Int. Cl. H01L 21/66; H01L 33/00; H01L 25/00; H01L 27/15

(52) U.S. Cl. CPC H01L 22/12; H01L 27/15; H01L 33/005; H01L 25/50; H01L 2933/0066

(57) ABSTRACT

A method of fabricating a light source includes providing a semiconductor light source emitting light when power is applied thereto, supplying power to the semiconductor light source, receiving light emitted by the semiconductor light source and performing a first measurement of optical properties of the received light, receiving light emitted by the semiconductor light source after a period of time has elapsed from the first measurement and performing a second measurement of optical properties of the received light, determining whether the semiconductor light source is defective or not by comparing the results of the first measurements of optical properties and the second measurements of optical properties, and constructing the light source including the semiconductor light source by providing peripheral parts thereof, wherein the semiconductor light source is determined as being normal as a result of determining whether the semiconductor light source is defective or not.

### CROSS-REFERENCE TO RELATED APPLICATION

This application claims priority under 35 U.S.C. §119 to Korean Patent Application No. 10-2014-0089793 filed on Jul. 16, 2014, with the Korean Intellectual Property Office, the entire disclosure of which is incorporated herein by reference.

### BACKGROUND

Semiconductor light-emitting devices emit light through electron-hole recombination in response to currents applied thereto and are widely used as light sources, due to several advantages thereof, such as lower power consumption, high luminance levels, and compactness, for example. Such devices have found wider use since nitride light-emitting devices were developed. For example, semiconductor light-emitting devices, such as light-emitting-diodes (LEDs), are being adopted for use in car headlights or in general illumination apparatuses, including house-lighting, for example. A semiconductor light source testing method allowing for the fabrication of a product having improved reliability and a semiconductor light source testing apparatus for such testing would be highly advantageous.

### SUMMARY

In exemplary embodiments in accordance with principles of inventive concepts, a method of fabricating a light source includes providing a semiconductor light source emitting light when power is applied thereto; supplying power to the semiconductor light source; receiving light emitted by the semiconductor light source and performing a first measurement of optical properties of the received light; receiving light emitted by the semiconductor light source after a period of time has elapsed from the first measurement and performing a second measurement of optical properties of the received light; determining whether the semiconductor light source is defective or not by comparing the results of the first measurements of optical properties and the second measurements of optical properties; and constructing the light source including the semiconductor light source by providing peripheral parts thereof, wherein the semiconductor light source is determined as being normal as a result of determining whether the semiconductor light source is defective or not.

In exemplary embodiments in accordance with principles of inventive concepts, a light source testing method includes test equipment determining whether the semiconductor light source is defective or not comprises: determining an amount of change in the optical property between the first and second measurements, based on the optical property obtained in the first measurement; and determining the semiconductor light source as being defective in if the calculated amount of change is equal to or greater than a predetermined value.

In exemplary embodiments in accordance with principles of inventive concepts, optical properties obtained in the first and second measurements are luminance levels of light emitted by the semiconductor light source in a method of fabricating a light source.

In exemplary embodiments in accordance with principles of inventive concepts, optical properties are obtained using a photodiode in a method of fabricating a light source.

In exemplary embodiments in accordance with principles of inventive concepts, optical properties obtained in the first and second measurements comprise color coordinate values of light emitted by the semiconductor light source in a method of fabricating a light source.

In exemplary embodiments in accordance with principles of inventive concepts, a light source testing method includes optical properties obtained using a spectrometer.

In exemplary embodiments in accordance with principles of inventive concepts, the performing of the first and second measurements includes obtaining first and second images by imaging the light emitted by the semiconductor light source, and the determining of whether the semiconductor light source is defective or not comprises comparing brightness levels of the first and second images and determining the semiconductor light source as being defective if the amount of change in the brightness level is equal to or greater than a predetermined value in a method of fabricating a light source.

In exemplary embodiments in accordance with principles of inventive concepts, a plurality of semiconductor light sources are tested, and the determining of whether the plurality of semiconductor light sources are defective or not comprises: setting segmentation regions corresponding to locations of the plurality of semiconductor light sources on each of the first and second images; and comparing the brightness levels of the first and second images for each of the segmentation regions and determining the semiconductor light source located in a location corresponding to the segmentation region as being defective if the amount of change in the brightness level is equal to or greater than a predetermined value in a method of fabricating a light source.

In exemplary embodiments in accordance with principles of inventive concepts, the light source is a light-emitting module; the semiconductor light source is a light-emitting device package including a package substrate having first and second terminals and a semiconductor light-emitting device on the package substrate and having first and second electrodes electrically connected to the first and second terminals; and the constructing of the light source comprises disposing the light-emitting device package determined as being normal as a result of determining whether the light-emitting device package is defective or not, on a module substrate in a method of fabricating a light source.

In exemplary embodiments in accordance with principles of inventive concepts, the first and second electrodes of the semiconductor light-emitting device are positioned to face the first and second terminals of the package substrate in a method of fabricating a light source.

In exemplary embodiments in accordance with principles of inventive concepts, the optical properties obtained in the first and second measurements are luminance levels of light emitted by the light-emitting device package, a time interval between the first measurement and the second measurement is 40 msec or less, and the light-emitting device package is determined as being defective if the amount of change in the luminance level between the first measurement and the second measurement is 5% or more, based on a luminance level obtained in the first measurement in a method of fabricating a light source.

In exemplary embodiments in accordance with principles of inventive concepts, the optical properties obtained in the first and second measurements are color coordinate values of light emitted by the light-emitting device package, a time interval between the first measurement and the second measurement is 40 msec or less, and the light-emitting device package is determined as being defective if an X color coordinate value obtained in the second measurement changes by 0.001 or more, based on an X color coordinate value obtained in the first measurement, or a Y color coordinate value obtained in the second measurement changes by 0.0006 or more, based on a Y color coordinate value obtained in the first measurement, based on the CIE 1931 color coordinates system in a method of fabricating a light source.

In exemplary embodiments in accordance with principles of inventive concepts, the semiconductor light source is a semiconductor light-emitting device including a conductive substrate and a light-emitting structure on the conductive substrate and having a first conductivity-type semiconductor layer, an active layer, and a second conductivity-type semiconductor layer in a method of fabricating a light source.

In exemplary embodiments in accordance with principles of inventive concepts, the light source is an illumination apparatus; the semiconductor light source is a light-emitting module including a module substrate and at least one of semiconductor light-emitting device and light-emitting device package on the module substrate; and the constructing of the light source comprises connecting a driver configured to control driving of the light-emitting module to the light-emitting module determined as being normal as a result of determining whether the light-emitting module is defective or not in a method of fabricating a light source.

In exemplary embodiments in accordance with principles of inventive concepts, the optical properties obtained in the first and second measurements are luminance levels of light emitted by the light-emitting module, a time interval between the first measurement and the second measurement is 0.5 sec or less, and the light-emitting module is determined as being defective if an amount of change in the luminance level between the first measurement and the second measurement is 5% or more, based on a luminance level obtained in the first measurement in a method of fabricating a light source.

In exemplary embodiments in accordance with principles of inventive concepts, the optical properties obtained in the first and second measurements are color coordinate values of light emitted by the light-emitting module, a time interval between the first measurement and the second measurement is 0.5 sec or less, and the light-emitting module is determined as being defective if an X color coordinate value obtained in the second measurement changes by 0.001 or more, based on an X color coordinate value obtained in the first measurement, or a Y color coordinate value obtained in the second measurement changes by 0.0006 or more, based on a Y color coordinate value obtained in the first measurement, based on the CIE 1931 color coordinates system in a method of fabricating a light source.

In exemplary embodiments in accordance with principles of inventive concepts, a plurality of semiconductor light sources are tested, and the performing of the first and second measurements includes receiving light emitted by each of the plurality of semiconductor light sources and performing the first and second measurements of the optical properties of the received light in a method of fabricating a light source.

In exemplary embodiments in accordance with principles of inventive concepts, a method of fabricating a light source includes storing a result of determining whether each of the plurality of semiconductor light sources is defective or not, in a memory device.

the light source is a light-emitting device package; the semiconductor light source is a semiconductor light-emitting device having first and second electrode structures and a package substrate having first and second terminals; and the constructing of the light source comprises forming an encapsulant on the semiconductor light-emitting device determined as being normal as a result of determining whether the semiconductor light-emitting device is defective or not in a method of fabricating a light source.

In exemplary embodiments in accordance with principles of inventive concepts, a semiconductor light source testing apparatus includes a power application unit configured to apply test power to a semiconductor light source to be tested; an optical property measurement unit configured to perform first and second measurements of optical properties of light emitted by the semiconductor light source at a time interval; and a defect determination unit configured to determine whether the semiconductor light source to be tested is defective or not by comparing resultant optical properties of the first and second measurements performed by the optical property measurement unit.

In exemplary embodiments in accordance with principles of inventive concepts, a semiconductor light source testing apparatus includes the defect determination unit calculates the amount of change in the optical property between the first measurement and the second measurement performed by the optical property measurement unit and determining the semiconductor light source as being defective if the calculated amount of change is equal to or greater than a predetermined value.

In exemplary embodiments in accordance with principles of inventive concepts, a semiconductor light source testing apparatus includes the optical property is at least one of a luminance level or a color coordinate value of light emitted by the semiconductor light source.

In exemplary embodiments in accordance with principles of inventive concepts, a semiconductor light source testing apparatus includes the optical property measurement unit includes at least one of a photodiode configured to measure the luminance level of light emitted by the semiconductor light source and a spectrometer configured to measure the color coordinate value of light emitted by the semiconductor light source.

In exemplary embodiments in accordance with principles of inventive concepts, a semiconductor light source testing apparatus includes the semiconductor light source is a light-emitting device package including a package substrate having first and second terminals and a semiconductor light-emitting device having first and second electrodes electrically connected to the first and second terminals.

In exemplary embodiments in accordance with principles of inventive concepts, a semiconductor light source testing apparatus includes the first and second electrodes of the semiconductor light-emitting device are positioned to face the first and second terminals of the package substrate.

In exemplary embodiments in accordance with principles of inventive concepts, a semiconductor light source testing apparatus includes the optical property is a luminance level of light emitted by the light-emitting device package, the time interval between the first measurement and the second measurement is 40 msec or less, and the defect determination unit determines the light-emitting device package as being defective if an amount of change in the luminance level between the first measurement and the second measurement is 5% or more, based on a luminance level obtained in the first measurement.

In exemplary embodiments in accordance with principles of inventive concepts, a semiconductor light source testing apparatus includes the optical properties obtained in the first and second measurements are color coordinate values of light emitted by the light-emitting device package, the time interval between the first measurement and the second measurement is 40 msec or less, and the defect determination unit determines the light-emitting device package as being defective if an X color coordinate value obtained in the second measurement changes by 0.001 or more, based on an X color coordinate value obtained in the first measurement, or a Y color coordinate value obtained in the second measurement changes by 0.0006 or more, based on a Y color coordinate value obtained in the first measurement, based on the CIE 1931 color coordinates system.

In exemplary embodiments in accordance with principles of inventive concepts, a semiconductor light source testing apparatus includes the semiconductor light source to be tested is a light-emitting module including a module substrate and at least one of a semiconductor light-emitting device and light-emitting device package on the module substrate.

In exemplary embodiments in accordance with principles of inventive concepts, a semiconductor light source testing apparatus includes the optical property is a luminance level of light emitted by the light-emitting module, the time interval between the first measurement and the second measurement is 0.5 sec or less, and the defect determination unit determines the light-emitting module as being defective if the amount of change in the luminance level between the first measurement and the second measurement is 5% or more, based on a luminance level obtained in the first measurement.

In exemplary embodiments in accordance with principles of inventive concepts, a semiconductor light source testing apparatus includes the optical properties obtained in the first and second measurements are color coordinate values of light emitted by the light-emitting module, the time interval between the first measurement and the second measurement is 0.5 sec or less, and the defect determination unit determines the light-emitting module as being defective if an X color coordinate value obtained in the second measurement changes by 0.001 or more, based on an X color coordinate value obtained in the first measurement, or a Y color coordinate value obtained in the second measurement changes by 0.0006 or more, based on a Y color coordinate value obtained in the first measurement, based on the CIE 1931 color coordinates system.

In exemplary embodiments in accordance with principles of inventive concepts, a semiconductor light source testing apparatus includes the optical property measurement unit includes an image capturing part configured to generate first and second images by firstly and secondly imaging the light emitted by the semiconductor light source in the time interval.

In exemplary embodiments in accordance with principles of inventive concepts, a semiconductor light source testing apparatus includes an image processor configured to calculate brightness levels of the first and second images, wherein the defect determination unit compares the brightness levels of the first and second images calculated in the image processor and determines the semiconductor light source as being defective if the amount of change in the brightness level is equal to or greater than a predetermined value.

In exemplary embodiments in accordance with principles of inventive concepts, a semiconductor light source testing apparatus includes a plurality of semiconductor light sources are to be tested, the image processing part sets segmentation regions corresponding to locations of the plurality of semiconductor light sources on the first and second images, and calculates brightness levels of the first and second images for each of the segmentation regions, and the defect determination unit compares the brightness levels of the first and second images for each of the segmentation regions and determines the semiconductor light source located in a location corresponding to the segmentation region as being defective if the amount of change in the brightness level is equal to or greater than a predetermined value.

In exemplary embodiments in accordance with principles of inventive concepts, a semiconductor light source testing apparatus includes the optical property measurement unit includes a sensor configured to measure an optical property of light emitted by the semiconductor light source, and a light-collecting part configured to guide the light emitted by the semiconductor light source to the sensor.

In exemplary embodiments in accordance with principles of inventive concepts, a semiconductor light source testing apparatus includes the light-collecting part includes at least one of an integrating sphere, an optical guide, and a light collector having an internal wall formed as a reflective surface.

In exemplary embodiments in accordance with principles of inventive concepts, a semiconductor light source testing apparatus includes a plurality of semiconductor light sources are to be tested, and the optical property measurement unit includes a plurality of sensors and a plurality of light-collecting parts corresponding to the plurality of semiconductor light sources, respectively.

In exemplary embodiments in accordance with principles of inventive concepts, a semiconductor light source testing apparatus includes the power application unit is attached to the optical property measurement unit to be formed integrally with the optical property measurement unit.

In exemplary embodiments in accordance with principles of inventive concepts, a semiconductor light source testing apparatus includes a memory configured to store a result of determining whether the semiconductor light source is defective or not, which is determined by the defect determination unit.

In exemplary embodiments in accordance with principles of inventive concepts, a semiconductor light source testing apparatus includes a plurality of semiconductor light sources to be tested, and the memory stores a result of determining whether each of the plurality of semiconductor light sources is defective or not.

.

In an embodiment, a plurality of light sources may be tested, and the memory stores a result of determining whether each of the plurality of light sources is defective or not.

In an embodiment, a method of testing a semiconductor light source includes a processor measuring the change in an optical characteristic of light emitted from a semiconductor light source over a period of the light source's operation; and a processor determining the semiconductor light source to be defective if the change in the light's optical characteristic exceeds a threshold amount.

In an embodiment, a method of testing a semiconductor light source includes a processor measuring the change in luminance of a semiconductor light source.

In an embodiment, a method of testing a semiconductor light source includes a processor measuring the change in a color coordinate value of a semiconductor light source.

In an embodiment, a method of testing a semiconductor light source includes a processor correlating a change in luminance values from the light source to junction temperature.

In an embodiment, a method of testing a semiconductor light source includes a processor correlating a change in color coordinate values from the light source to junction temperature.

In an embodiment, a method of testing a semiconductor light source includes a processor correlating a junction temperature to a thermal resistance.

### BRIEF DESCRIPTION OF DRAWINGS

The above and other aspects, features and other advantages in the present disclosure will be more clearly understood from the following detailed description taken in conjunction with the accompanying drawings, in which:

FIG. 1 is a flowchart illustrating a light source testing method in accordance with principles of inventive concepts;

FIG. 2 is a diagram schematically illustrating a light source testing apparatus in accordance with principles of inventive concepts;

FIG. 3 is a diagram illustrating a modified embodiment of the light source testing apparatus according to the embodiment illustrated in FIG. 2;

FIGS. 4A to 4C are diagrams illustrating optical property measurement units employed in a light source testing apparatus in accordance with principles of inventive concepts;

FIGS. 5 to 8 are graphs illustrating a principle of defect determination in a light source testing method in accordance with principles of inventive concepts;

FIG. 9 and FIGS. 10A to 10C are diagrams illustrating a defect determination method in a light source testing method according to an embodiment of the present disclosure;

FIG. 11 is a flowchart illustrating a method of fabricating a light-emitting device package in accordance with principles of inventive concepts;

FIG. 12 is a process cross-sectional view illustrating a process step of the manufacturing method of FIG. 11;

FIGS. 13A to 13C are process cross-sectional views illustrating a method of fabricating a light-emitting device package according to the method described with reference to FIG. 11;

FIGS. 14A and 14B are diagrams exemplarily illustrating light-emitting device packages fabricated via the method of FIG. 11;

FIG. 15 is a flowchart illustrating a method of fabricating a light-emitting module in accordance with principles of inventive concepts;

FIGS. 16A and 16B are process cross-sectional views illustrating the method of fabricating a light-emitting module according to the embodiment of FIG. 15;

FIG. 17 is a flowchart illustrating a method of fabricating an illumination apparatus in accordance with principles of inventive concepts;

FIGS. 18A and 18B are process cross-sectional views illustrating the method of fabricating an illumination apparatus according to the embodiment of FIG. 17;

FIGS. 19 and 20 are exploded perspective views schematically illustrating illumination apparatuses fabricated according to embodiments in the present disclosure;

FIGS. 21 and 22 are cross-sectional views illustrating embodiments in which an illumination apparatus fabricated in accordance with principles of inventive concepts is applied to a backlight unit; and

FIG. 23 is a cross-sectional view illustrating an embodiment in which an illumination apparatus fabricated in accordance with principles of inventive concepts is applied to a headlamp.

### DETAILED DESCRIPTION

Various embodiments will be described more fully hereinafter with reference to the accompanying drawings, in which some embodiments are shown. Inventive concepts may, however, be embodied in many different forms and should not be construed as limited to the embodiments set forth herein. Rather, these embodiments are provided so that this description will be thorough and complete, and will convey the scope of inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items and the term “or” is meant to be inclusive, unless otherwise indicated.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of inventive concepts. The thickness of layers may be exaggerated for clarity.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of inventive concepts.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In exemplary embodiments in accordance with principles of inventive concepts a semiconductor light source may be tested for defects by indirectly measuring the device's thermal resistance. A relatively high thermal resistance may indicate a flaw, for example, in the junction between a semiconductor light source and a package substrate. A crack, a void, or a cold solder joint may be the cause of such a defect. Light or, more specifically, changes in characteristics of light emitted by a semiconductor light source may be used in accordance with principles of inventive concepts to detect semiconductor light sources having relatively high junction temperatures. The relatively high junction temperatures may be correlated with relatively high thermal resistance: an indication of a defect. In embodiments in accordance with principles of inventive concepts, a change in luminance or a change in color coordinate values may be the light characteristic employed to correlate with junction temperature and, in turn, with thermal resistance. In embodiment in accordance with principles of inventive concepts, on or more processors, such as may be associated with test equipment, may be employed in the light-characteristic measurement, correlation and defect determination processes.

By correlating junction temperature with thermal resistance and by further correlating junction temperature with luminance changes a system and method in accordance with principles of inventive concepts may test semiconductor light sources conveniently, efficiently, and thoroughly. Correlations between junction temperature and thermal resistance may be established empirically for devices of a particular design, for example, and used for testing all devices of that particular design. Similarly, correlations between luminance changes and junction temperature may be established empirically for devices of a particular design, for example, and used for testing all devices of that particular design.

Alternatively, or in addition to correlating junction temperature with luminance changes, by correlating junction temperature with thermal resistance and by further correlating junction temperature with color coordinate changes a system and method in accordance with principles of inventive concepts may test semiconductor light sources conveniently, efficiently, and thoroughly. Correlations between junction temperature and thermal resistance may be established empirically for devices of a particular design, for example, and used for testing all devices of that particular design. Similarly, correlations between color coordinate changes and junction temperature may be established empirically for devices of a particular design, for example, and used for testing all devices of that particular design.

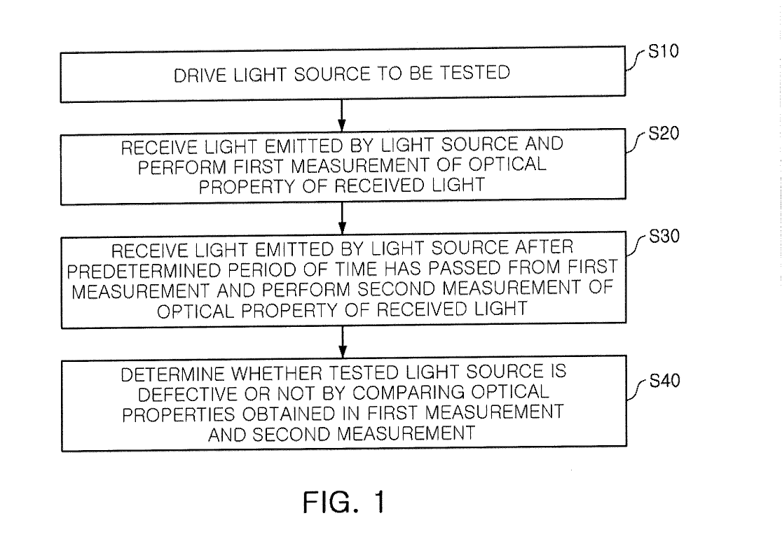

FIG. 1 is a flowchart illustrating an embodiment of a light source testing method according to an embodiment in the present disclosure. The light source testing method may include driving a light source to be tested (S10). Any type of semiconductor light source may be used as long as it emits light when driving power is applied thereto. More specifically, the light source may be a semiconductor light-emitting device, or a light-emitting device package, light-emitting module, or illumination apparatus using the semiconductor light-emitting device, for example. In embodiments, a light-emitting device package 1 tested in the embodiment of FIG. 1 may be a bare package, in a state before an encapsulant is formed thereon.

Next, the light source testing method in accordance with principles of inventive concepts may include receiving light emitted from the light source to be tested and performing a first measurement (S20) and a second measurement (S30) of the optical property of the received light. The second measurement may be performed after a predetermined period of time has passed from the first measurement.

Next, the method may include comparing the values of optical properties obtained in the first and second measurements and determining whether the tested light source is defective or not according to a result of the comparison (S40). For example, a tested optical property may be at least one of a luminance level and a color coordinate value of light emitted by the light source to be tested.

Hereinafter, the above-described light source testing method will be described in greater detail, along with a light source testing apparatus in which the light source testing method in accordance with principles of inventive concepts is performed.

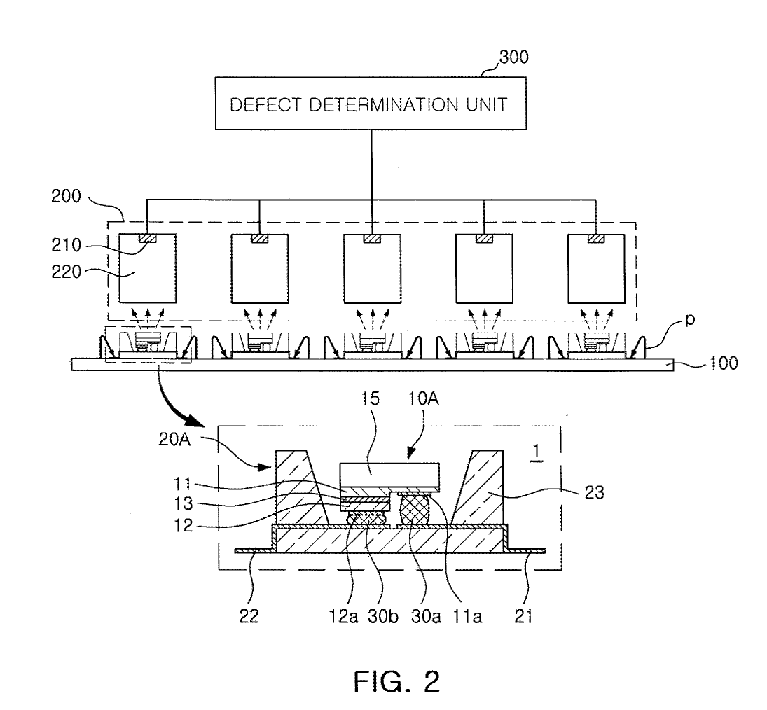

FIG. 2 is a diagram schematically illustrating a light source testing apparatus in accordance with principles of inventive concepts. The light source testing apparatus may include a power application unit 100 for applying test power to the light source to be tested, optical property measurement unit 200, and a defect determination unit 300 for determining whether the light source is defective or not.

The light source to be tested may be a light-emitting device package 1 including a package substrate 20A and a semiconductor light-emitting device 10A, such as a light emitting diode (LED), disposed on the package substrate 20A.

The semiconductor light-emitting device 10A may include, for example, a substrate 15, a light-emitting structure, and first and second electrodes 11a and 12a disposed on the light-emitting structure.

The substrate 15 may be provided as a semiconductor growth substrate and may be formed of an electrically insulating or conductive material, for example, sapphire, SiC, MgAl₂O₄, MgO, LiAlO₂, LiGaO₂, and GaN.

The light-emitting structure may include, for example, first and second conductivity-type semiconductor layers 11 and 12 and an active layer 13 disposed therebetween. The first and second conductivity-type semiconductor layers 11 and 12 may be, but are not limited to, n-type and p-type semiconductor layers, respectively. In this embodiment, the first and second conductivity-type semiconductor layers 11 and 12 may have an empirical formula of AlₓIn_{y}Ga_{(1-x-y})N (wherein, 0≦x≦1, 0≦y≦1, and 0≦x+y≦1), and may include a material such as GaN, AlGaN, or InGaN. The active layer 13 formed between the first and second conductivity-type semiconductor layers 11 and 12 may emit light having a predetermined amount of energy by electron-hole recombination, and have a multi-quantum-well (MQW) structure, for example, an InGaN/GaN structure, in which quantum well layers and quantum barrier layers are alternately stacked.

The first and second electrodes 11a and 12a may be formed respectively on the first and second conductivity-type semiconductor layers 11 and 12, and may include one or more electrically conductive materials well-known in the art, such as Ag, Al, Ni, Cr, Cu, Au, Pd, Pt, Sn, W, Rh, Ir, Ru, Mg, Zn, Ti, and an alloy including thereof, for example.

The package substrate 20A may include a package body 23, and first and second terminals 21 and 22. The package body 23 may function to support the first and second terminals 21 and 22, and may be formed of an opaque or high-reflective resin. For example, the package body 23 may be formed using a polymeric resin, which is suitable for an injection process, for example. The package body 23 may be formed of any of a variety of non-conductive materials. The first and second terminals 21 and 22 may be formed of a metal having a high level of electrical conductivity. The first and second terminals 21 and 22 may be electrically connected to the first and second electrodes 11a and 12a of the semiconductor light-emitting device 10A to transfer driving power received from the outside (that is, off device 1) to the semiconductor light-emitting device 10A.

In this embodiment, the first and second electrodes 11a and 12a of the semiconductor light-emitting device 10A may be disposed to face the first and second terminals 21 and 22 of the package substrate 20A, and may be electrically connected to each other via first and second bumps 30a and 30b, for example.

In an embodiment of a light source testing method described with reference to FIG. 1, operation S10 of driving the light source to be tested may be performed using the power application unit 100 of the light source testing apparatus.

That is, the power application unit 100 may apply test power to the light source to be tested so that the light source emits light. The power application unit 100 may include, for example, a plurality of probes P. The plurality of probes P may be in contact with the first and second terminals 21 and 22 included in the light-emitting device package 1 to transmit the test power.

In the light source testing method according to the embodiment described with reference to FIG. 1, operations (S20 and S30) of performing first and second measurements of the optical properties of light emitted by the light source may be performed using optical property measurement unit 200 of the light source testing apparatus.

In exemplary embodiments in accordance with principles of inventive concepts, the optical property measurement unit 200 may receive the light emitted by the light source at a predetermined time interval and perform the first and second measurements of the received light.

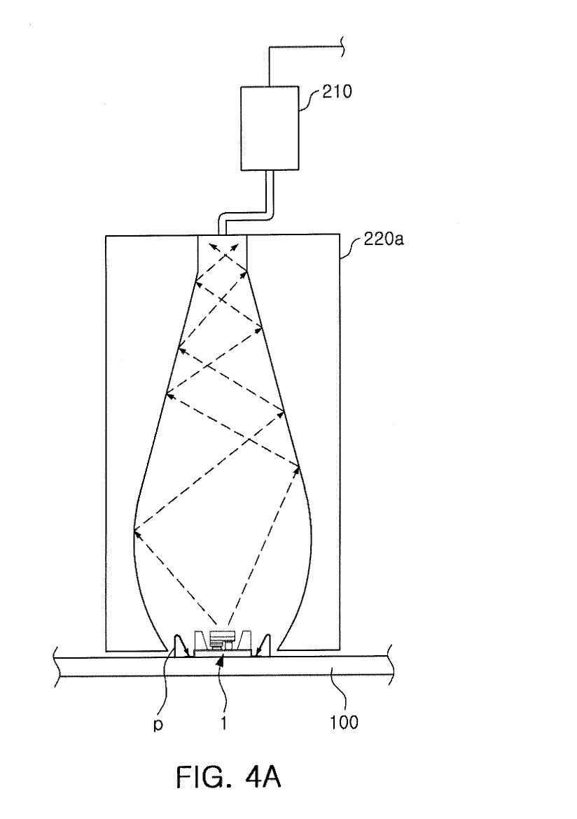

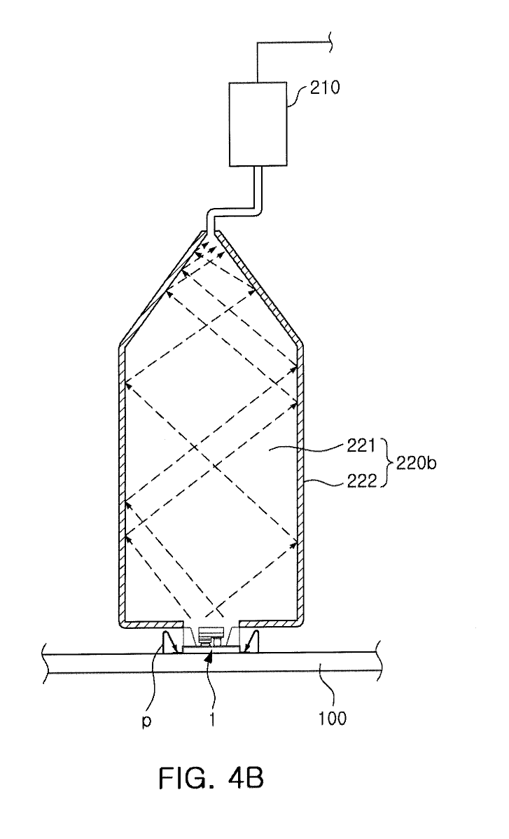

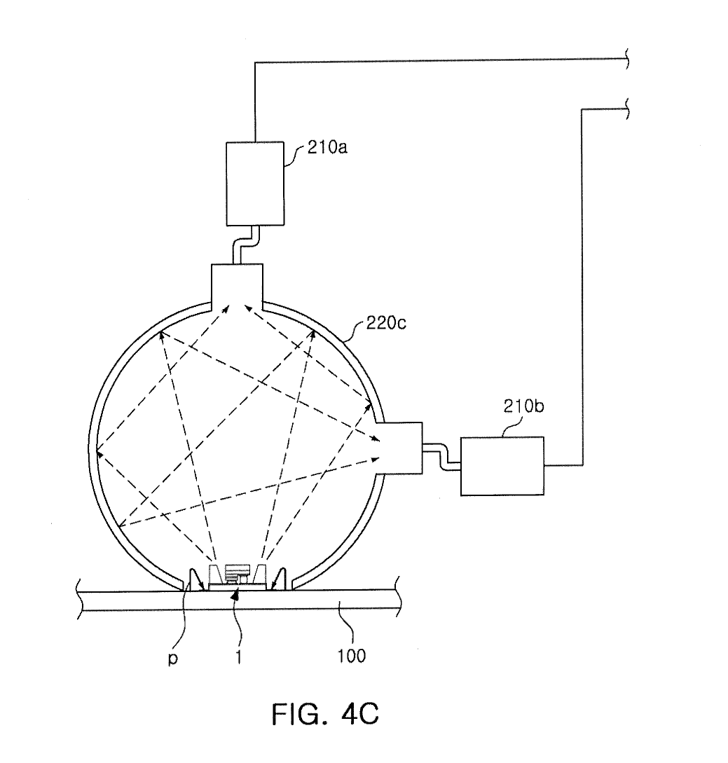

The optical property measurement unit 200 may include, as will be described later in FIGS. 4A to 4C, a sensor 210 configured to measure an optical property, and a light-collecting part 220 configured to guide the light emitted from the light source to the sensor 210. The optical property may be at least one of a luminance level and a color coordinate value of the received light, for example. The sensor 210 may include at least one photodiode for measuring the luminance level or a spectrometer for measuring the color coordinate value.

As illustrated in FIG. 2, in an embodiment in accordance with principles of inventive concepts, a plurality of light sources may be tested simultaneously. In order to determine whether each of the plurality of light sources is defective or not, the light source testing method may include, for example, receiving light emitted by each of the plurality of light sources, and performing first and second measurements of the optical properties of the received light and the optical property measurement unit 200 may include a plurality of light collectors 220 and a plurality of sensors 210 corresponding to the plurality of light sources.

In the light source testing method according to the embodiment described with reference to FIG. 1, operation S40 of determining whether the light source is defective or not may include calculating the amount of change in an optical property between the first and second measurements performed by the optical property measurement unit 200, and determining the light source to be defective if the calculated amount of change is equal to or greater than a predetermined value (that is, a threshold value). For this, the light source testing apparatus may include the defect determination unit 300 capable of performing the above-described operations.

In embodiments defect determination unit 300 may include an analog-to-digital converter (AD converter) converting the optical property measured by the sensor 210 of the optical property measurement unit 200 to electrical signals. The defect determination unit 300 may compare results of the first and second measurements of the optical properties, and determine whether the light source is defective or not. For example, the defect determination unit 300 may calculate the amount of change in the optical property between the first and second measurements, based on the optical property obtained in the first measurement, and determine the light source as being defective if the calculated amount of change is equal to or greater than a predetermined value.

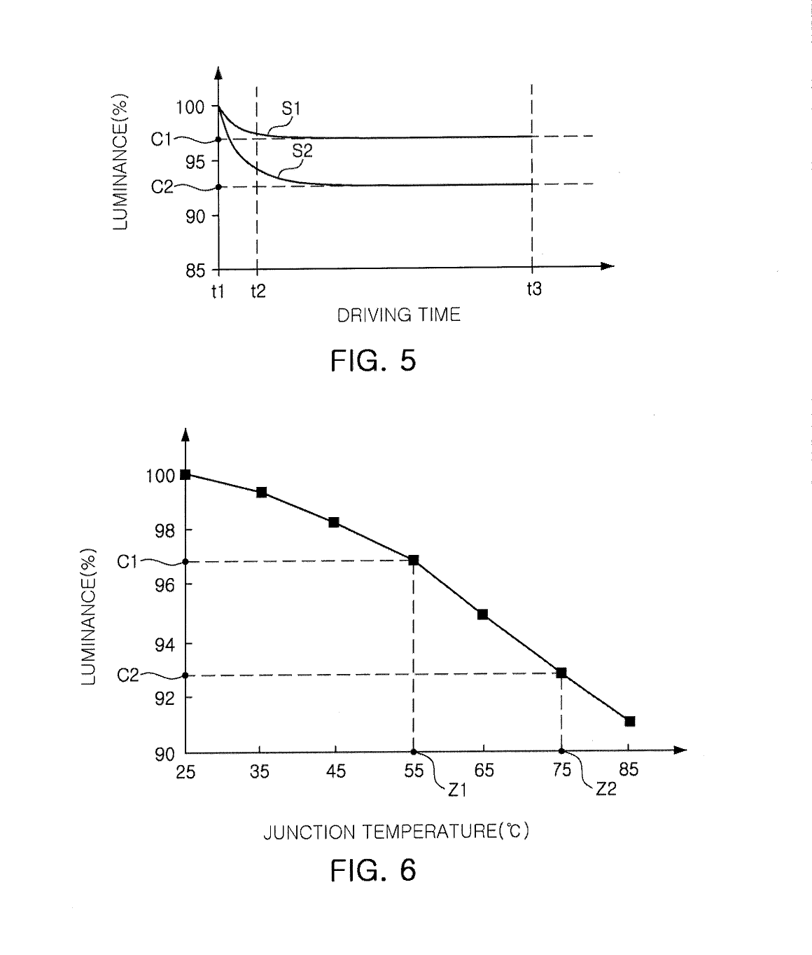

An embodiment of defect determination unit 300 in accordance with principles of inventive concepts will be described in greater detail in the discussion related to FIGS. 5 to 10.

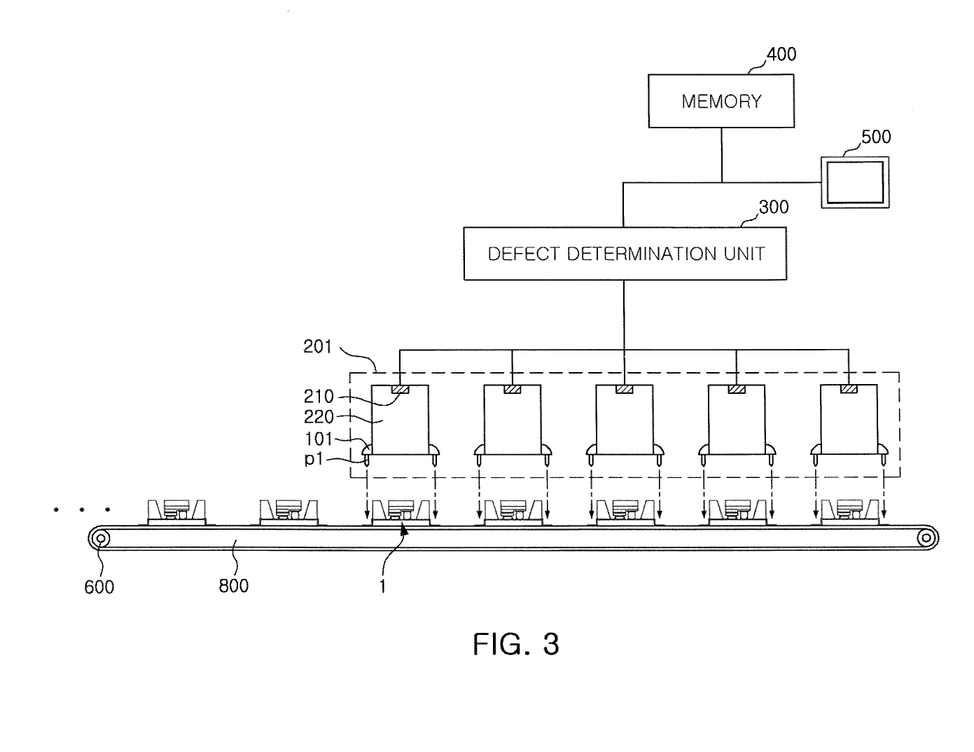

FIG. 3 is a diagram illustrating an example embodiment of the light source testing apparatus in accordance with principles of inventive concepts, similar to that of the embodiment illustrated in FIG. 2. Light source testing apparatus may include a power supply 101, an optical property measurement unit 201, and a defect determination unit 300. Hereinafter, descriptions of the same components as those in previously described embodiments will not be repeated, with the emphasis being placed on a description of new, that is, not previously described herein, components.

In this embodiment, the power supply 101 may include a probe p1 configured to transmit test power to a light source to be tested. In this embodiment, the probe p1 may be, as illustrated in FIG. 3, attached to the optical property measurement unit 201. The power supply 101 may be integrally formed with the optical property measurement unit 201.

The light source testing apparatus may include a tray 800 in which the light source to be tested may be disposed. In addition, the light source testing apparatus may include a transport part 600 for changing the location of the light source disposed in the tray 800. The transport part 600 may include, for example, a conveyer belt.

In a light source testing method according to an embodiment with reference to FIG. 1, the transport part 600 may remove a test-finished light source from among the light sources to be tested from a location in which the optical property thereof is measured, by the transport part 600, and transporting a light source not yet tested to the location, for example, a location corresponding to the optical property measurement unit 201.

The light source testing apparatus may include a display 500 for displaying a result that indicates whether the light source is defective or not, as determined by the defect determination unit 300, and a memory 400 for storing the result indicating whether the light source is defective or not. In exemplary embodiments in accordance with principles of inventive concepts in which a plurality of light sources are tested, the display 500 may display whether each of the plurality of light sources is defective or not and the memory 400 may store the result indicating whether each of the plurality of light sources is defective or not. In such embodiments, the light source testing method according to the embodiment described with reference to FIG. 1 may include storing the result indicating whether each of the plurality of light sources is defective or not in the memory 400.

Hereinafter, the optical property measurement unit 200 employed in the light source testing apparatus according the embodiments of FIGS. 2 and 3 will be described in greater detail, with reference to FIGS. 4A to 4C. FIGS. 4A to 4C are diagrams illustrating optical property measurement units 200 employed in a light source testing apparatus in accordance with principles of inventive concepts.

As illustrated in FIG. 4A, the optical property measurement unit 200 may include a sensor 210 configured to measure an optical property of light emitted by a light source. The sensor 210 may include at least one photodiode for measuring a luminance level or a spectrometer for measuring a color coordinate value, for example.

The optical property measurement unit 200 may include a light-collecting part 220 for guiding light emitted by the light source to be tested to the sensor 210. The light-collecting part 220 may be a light collector 220a having an internal wall provided as a reflective surface. The internal wall of the light collector 220a may have a curved surface (a parabolic surface, for example) to effectively guide light emitted from side and top surfaces of the light source to the sensor 210.

In addition, the light-collecting part 220 may include a light guide 220b as illustrated in FIG. 4B. The light guide 220b may perform first and second measurements of the optical properties in a state of being in contact with the light source so that light emitted by the light source is not released to the outside during the first and second measurements. The light guide 220b may include, for example, a core 221 and a cladding 222 surrounding the core 221. The core 221 and the cladding 222 may have different refractive indexes so that total reflection may occur at an interface thereof. For example, the core 221 may have a greater refractive index than the cladding 222.

Alternatively, the light-collecting part 220 may include an integrating sphere 220c as illustrated in FIG. 4C. The integrating sphere 220c may function to uniformly spread light emitted from a particular direction over an entire inner spherical surface, and the optical property may be measured by detecting light at a portion of the inner spherical surface.

A light source testing method according to the embodiment described with reference to FIG. 1 may include determining whether the tested light source is defective or not by considering both the amount of change in the luminance level and the amount of change in the color coordinate value obtained in the first and second measurements. More specifically, operation S40 of determining whether the light source is defective or not may include determining the amount of change in each of the luminance level and the color coordinate value between the first and second measurements, based on the luminance level and the color coordinate value obtained in the first measurement, and determining the light source as being defective if both of the amount of change in the luminance level and the amount of change in the color coordinate value are equal to or greater than predetermined values.

In exemplary embodiments in accordance with principles of inventive concepts, the defect determination unit 300 included in the light source testing apparatus may be implemented to determine whether the light source is defective or not by considering both the amount of change in the luminance level and the amount of change in the color coordinate value, and, to that end, the optical property measurement unit 200 may include sensors 210a and 210b as illustrated in FIG. 4C. Each of the sensors 210a and 210b may include a photodiode and/or a spectrometer, for example.

Hereinafter, the principles of defect determination in a light source testing method in accordance with principles of inventive concepts will be described in detail with respect to FIGS. 5 to 7.

FIG. 5 is a graph illustrating the amount of change in the luminance level of the light source according to the driving time when a light source to be tested is driven by applying test power thereto. FIG. 6 is a graph illustrating the amount of change in the luminance level according to a junction temperature of a light source. The junction temperature may refer to an average temperature at a junction area while the semiconductor light-emitting device 10A is operated, and may be measured and calculated using a thermal resistance measuring device, for example.

As illustrated in FIG. 5, two light source samples S1 and S2 in the graph may be described as the light sources to be tested. In this example the first measurement is performed at time t1 and the second measurement is performed at time t3. In the first light source sample S1, a luminance level obtained in the second measurement is about 97% (please see mark C1), that is, reduced by about 3%, based on a luminance level (100%) obtained in the first measurement. On the other hand, in the second light source sample S2, (which is, in an embodiment, fabricated via the same process as the first light source sample) a luminance level obtained in the second measurement is about 93% (please see mark C2), that is, reduced by about 7%, based on a luminance level (100%) obtained in the first measurement. As such, the luminance level of light emitted from the light source decreases as driving time of the light source increases. Such changes may be because the energy bandgap of the semiconductor light-emitting device 10A is lowered as a junction temperature increases, and thus a change in a forward bias of the semiconductor light-emitting device 10A occurs.

In the light source testing method in accordance with principles of inventive concepts, when the semiconductor light-emitting device 10A is driven by test power, the light source may be heated by heat emitted by the semiconductor light-emitting device 10A, and thus, junction temperature may rise during a time interval between the first measurement and the second measurement. Accordingly, the luminance level may be decreased.

Referring to FIG. 6, a junction temperature may be derived, based on the amount of change in the luminance level. Accordingly, a junction temperature (about 75° C., please see mark Z2) of the second light source sample is higher than a junction temperature (about 55° C., please see mark Z1) of the first light source sample which exhibits a smaller reduction in luminance level than the second light source sample. A luminance/junction temperature relationship such as plotted in FIG. 6 may be determined experimentally, for example.

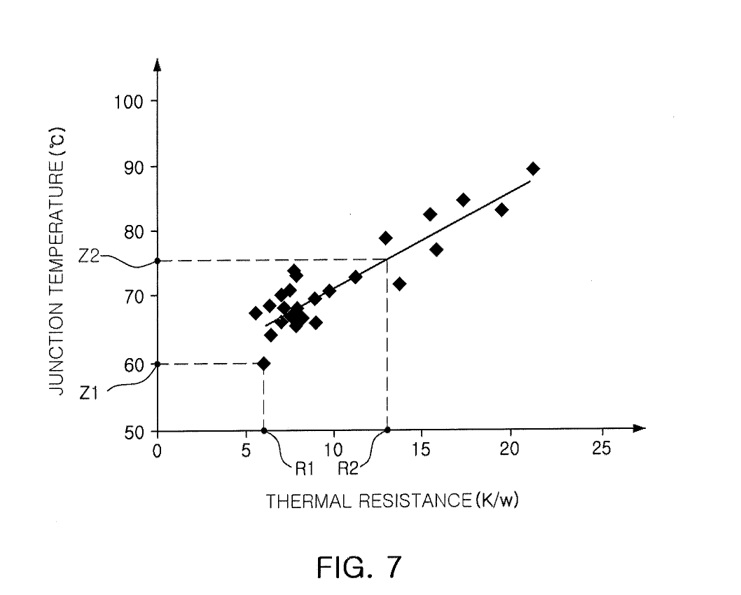

Given junction temperature, levels of thermal resistance of the first and second light source samples may be derived from a relationship between junction temperature and thermal resistance, such as plotted in FIG. 7. The levels of thermal resistance of the first and second light source samples may be derived as R1 and R2, respectively, in this embodiment.

When a defect occurs in a junction interface between the package substrate 20A and the semiconductor light-emitting device 10A, thermal resistance may increase because heat generated in the semiconductor light-emitting device 10A is difficult to dissipate to the outside through the junction interface. For example, referring to the light-emitting device package 1 illustrated in FIG. 2, the thermal resistance may increase if a defect, such as a crack, a void, or cold solder joint, is generated in the first and second bumps 30a and 30b. Accordingly, if thermal resistance of the light source to be tested is higher than a certain reference level; a defect may exist in the junction interface. A light source testing method in accordance with principles of inventive concepts makes it possible to determine whether the light source is defective or not (for example, whether the light source has a junction defect or not) by comparing the amount of change in the luminance level according to the time interval between the first and second measurements, using a relationship between the thermal resistance and the junction temperature and a relationship between the junction temperature and the amount of change in the luminance level. The light source testing method in accordance with principles of inventive concepts may be more readily implemented than a method of directly measuring and calculating thermal resistance, or an X-ray testing method, to determine the presence of a defect in a junction interface, and may determine even a fine defect in a junction interface. In addition, because an increase in junction temperature is induced using heat generated by driving the light source, an additional apparatus for heating the light source may not be required. Accordingly, implementation of a light source testing apparatus and a light source testing method in accordance with principles of inventive concepts may be simpler and more efficient than conventional approaches.

As an example, in a light source testing method in accordance with principles of inventive concepts, in the case in which a light source to be tested is a light-emitting device package 1 as illustrated in FIG. 2 and a time interval between the first measurement and the second measurement is 40 msec or less, the light-emitting device package 1 may be determined as being defective if the amount of change of the luminance level between the first and second measurements is 5% or more, based on a luminance level obtained in the first measurement (that is, a 5% or more excursion from the first measurement), for example. It was experimentally discovered that if the amount of change in the luminance level is 5% or more when driving the light-emitting device package 1 for a very short time, about 40 msec, the light-emitting device package 1 is defective, that is, has a junction temperature of 65° C. or more and a thermal resistance of 10 K/W or more in the second measurement.

Accordingly, the defect determination unit 300 included in the light source testing apparatus in accordance with principles of inventive concepts may determine that a tested light source is defective if the amount of change in the luminance level between the first and second measurements is 5% or more, based on a luminance level obtained in the first measurement. In embodiments, the optical property measurement unit 200 may set the time interval between the first measurement and the second measurement to be 40 msec or less. However, the time interval between the first measurement and the second measurement, the amount of change in luminance level, which is a criteria of a defect determination, the above-described junction temperature and thermal resistance, and the like may be set differently depending on a type of the light source to be tested. In exemplary embodiments in accordance with principles of inventive concepts, for example, a semiconductor light-emitting device, a light-emitting device package, a light-emitting module, and an illumination apparatus are light sources that may be tested. In addition, that the time interval, the amount of change in luminance level, junction temperature, thermal resistance, and the like may be differently set depending on a material of the light source, a physical shape and structure of the light source, and the like, even if the same type of light source is tested.

Referring to FIG. 5, the above described second measurement is illustrated as starting at the time t3 at which the amount of change in the luminance level is saturated, but a method in accordance with principles of inventive concepts is not limited thereto. For example, the second measurement may start at the time t2 at which the amount of change in the luminance level is not saturated yet.

In addition, the above-described values of the amount of change in the luminance level, junction temperature, and thermal resistance are only provided for easier understanding of example embodiments and are not intended to limit the scope of inventive concepts.

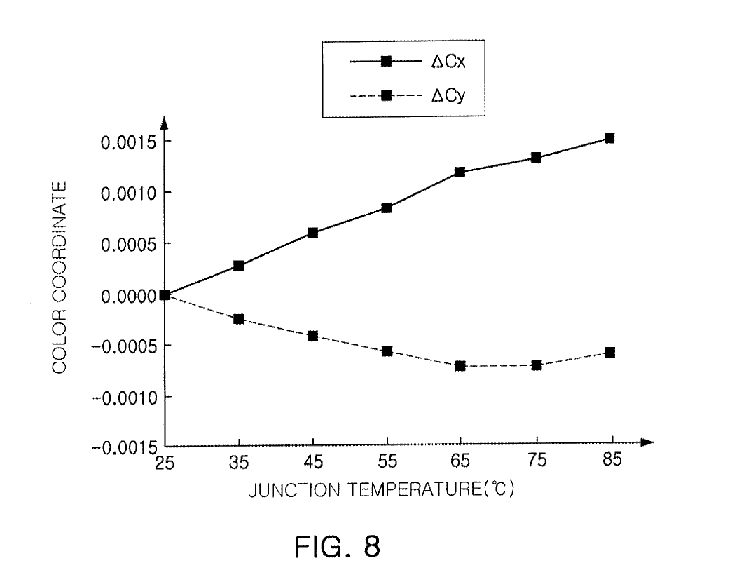

FIG. 8 is a diagram illustrating a principle in defect determination of a light source testing method in accordance with principles of inventive concepts. FIG. 8 is a graph illustrating the amount of movement in the color coordinate value of a light source according to the junction temperature, which may be determined experimentally, for example. In this embodiment, the optical properties measured in the first and second measurements may be a color coordinate value. The color coordinate value may be, for example, a value in a CIE 1931 XY color coordinate system.

As the junction temperature increases, the energy bandgap of the semiconductor light-emitting device 10A may change. Accordingly, as illustrated in FIG. 8, a Cx-axis color coordinate value of light emitted by the semiconductor light-emitting device 10A may move in a (+) direction, and a Cy-axis color coordinate value of the light emitted by the semiconductor light-emitting device 10A may move in a (−) direction.

From such excursions it may be inferred whether a thermal resistance of the tested light source is higher than a certain criteria or not, using a relationship between the junction temperature and the amount of movement of the color coordinate value and a relationship between the thermal resistance and the junction temperature described with reference to FIG. 7. Accordingly, it may be determined whether the light source is defective or not, in accordance with principles of inventive concepts.

In a light source testing method in accordance with principles of inventive concepts, if a light source to be tested is the light-emitting device package 1 as illustrated in FIG. 2 and a time interval between the first measurement and the second measurement is 40 msec or less, the light-emitting device package 1 may be determined to be defective if an X color coordinate value obtained in the second measurement changes by 0.001 or more, based on an X color coordinate value obtained in the first measurement, or a Y color coordinate value obtained in the second measurement changes by 0.0006 or more, based on a Y color coordinate value obtained in the first measurement, for example. It has been experimentally found that if the above described amount of change in the color coordinate value occurs if driving the light-emitting device package 1 for a very short time, about 40 msec, the light-emitting device package 1 is defective, that is, a junction temperature is 65° C. or more and a thermal resistance is 10 K/W or more in the second measurement.

Accordingly, the defect determination unit 300 included in the light source testing apparatus in accordance with principles of inventive concepts may determine that the light-emitting device package 1 is detective when an X color coordinate value obtained in the second measurement changes by 0.001 or more, based on an X color coordinate value obtained in the first measurement, or a Y color coordinate value obtained in the second measurement changes by 0.0006 or more, based on a Y color coordinate value obtained in the first measurement. In embodiments, the optical property measurement unit 200 may set the time interval between the first measurement and the second measurement to be 40 msec or less. In exemplary embodiments in accordance with principles of inventive concepts, as previously described, the time interval between the first measurement and the second measurement, the amount of movement of the color coordinate value, which is a criteria of a defect determination, the above-described junction temperature and thermal resistance, and the like may be set differently depending on a type of the light source to be tested, the physical shape and structure of the light source, or the material of the light source, for example.

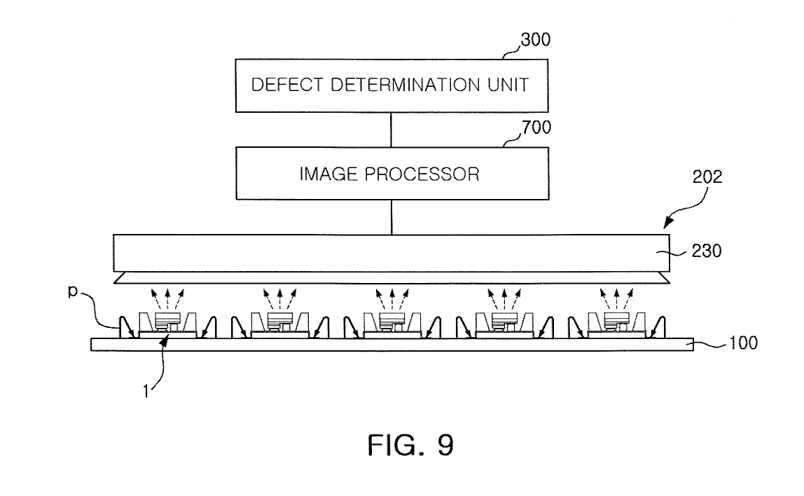

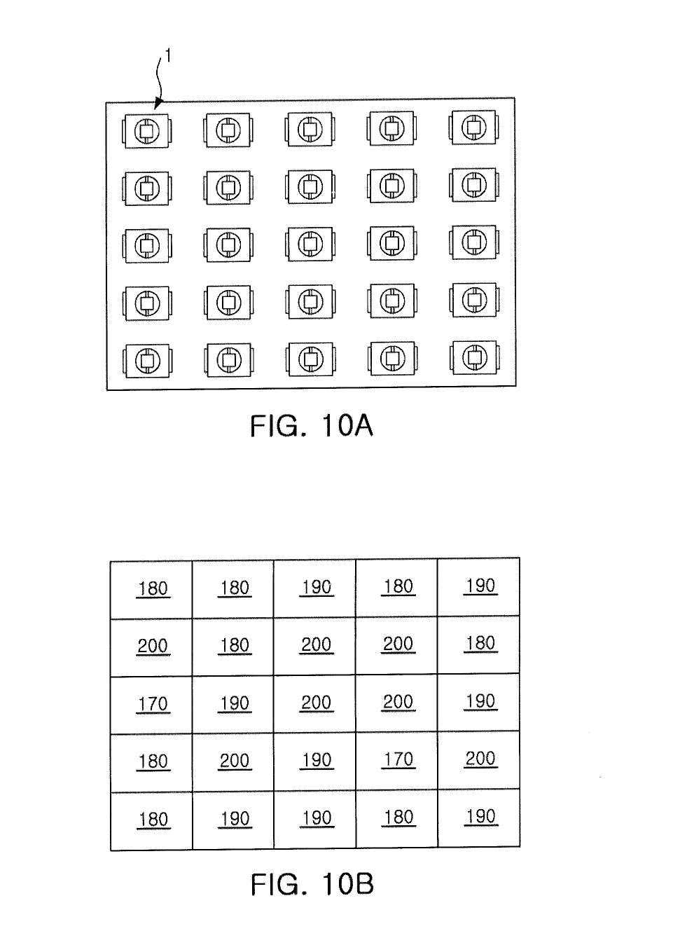

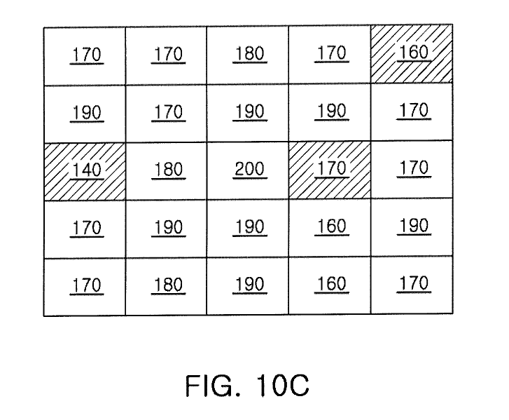

FIG. 9 and FIGS. 10A to 10C are diagrams illustrating a defect determination method in a light source testing method in accordance with principles of inventive concepts. In the light source testing method according to the embodiment described with reference to FIG. 1, steps S30 and S40 of performing first and second measurements may include imaging light emitted by the light source to obtain first and second images. For such measurements, optical property measurement unit 200 of the light source testing apparatus may include an image capturing part 230, as illustrated in FIG. 9. The image capturing part 230 may include, for example, a CCD camera module, and may generate first and second images by firstly and secondly imaging light emitted by the light source at a predetermined time interval.

Next, the example light source testing method may include determining whether the tested light source is defective or not using the first image and the second image. In exemplary embodiments in accordance with principles of inventive concepts, the light source testing method may include comparing brightness levels of the first and second images and determining the light source as being defective if the amount of change in the brightness level is equal to or greater than a predetermined value. In such embodiments, the light source testing apparatus of FIG. 9 may include an image processor 700 that measures and calculates the brightness levels of the first and second images, and a defect determination unit 300 that compares the brightness levels of the first and second images determined in the image processor 700 and determining whether the amount of change in the brightness level is equal to or greater than a predetermined value

In embodiments, the image processor 700 may convert the first and second images into grayscale. Since information of the image converted into the grayscale is related to brightness information, the defect determination unit 300 may more accurately compare the amount of change in the brightness level using such a grayscale conversion. In embodiments, the brightness level may be understood as referring to a gray level by which an image is binarized to determine intensity values within the numerical range of 0 to 255.

Operation of the defect determination unit 300 will be described in detail with reference to FIGS. 10A to 10C. FIG. 10A schematically illustrates images imaged by the image capturing part 230. As illustrated in FIG. 10A, a plurality of light sources may be tested. FIGS. 10B and 10C schematically illustrate a state in which brightness levels of the first and second images are calculated by image processor 700, respectively. In particular, if the plurality of light sources are tested, the image processor 700 may set segmentation regions corresponding to locations of the plurality of light sources on each of the first and second images, and calculate the brightness levels of the first and second images for each segmentation region.

In such an embodiment, the defect determination unit 300 may compare the brightness levels of the first and second images calculated in the image processor 700 for each segmentation region, and determine the light source located in a location corresponding to the segmentation region as being defective if the amount of change in the brightness level is equal to or greater than a predetermined value (that is, a threshold value).

For example, if the defect determination unit 300 is set to determine a light source as being defective if the brightness level of the second images is reduced by 30 grayscale steps or more, based on brightness level of the first image, light sources located at row 1 and column 5, row 3 and column 1, and row 3 and column 4 may be determined as being defective referring to FIGS. 10B and 10C (with initial values in FIG. 10B and subsequent values in FIG. 10C).

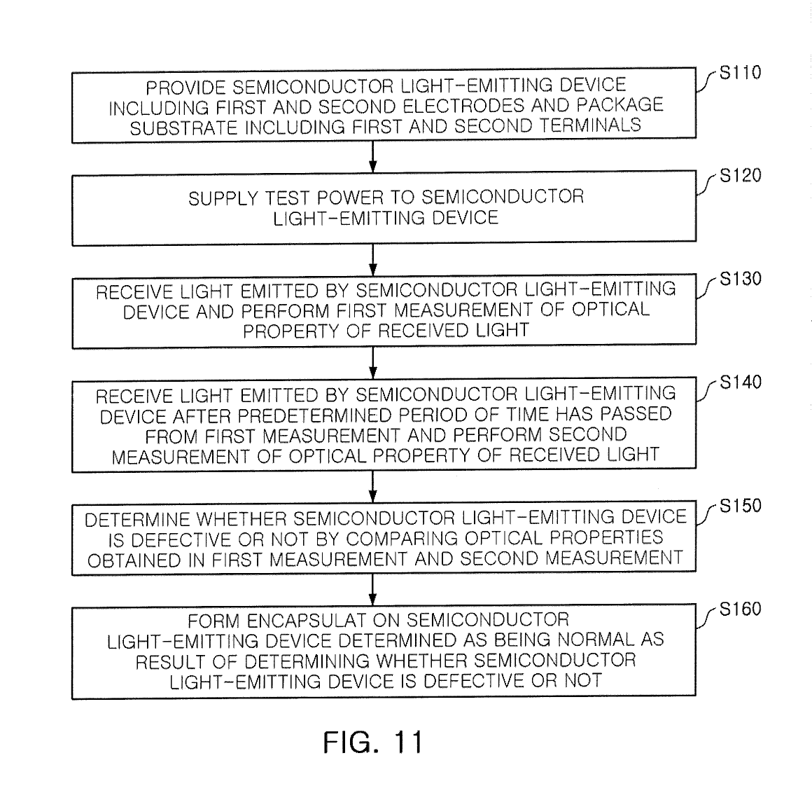

FIG. 11 is a flowchart illustrating an example method of fabricating a light-emitting device package in accordance with principles of inventive concepts, which may include providing a semiconductor light-emitting device 10A including first and second electrodes 11a and 12a, and a package substrate 20A including first and second terminals 21 and 22 (S110).

In addition, the method may include supplying test power to the semiconductor light-emitting device 10A in order to drive the semiconductor light-emitting device 10A (S120). The method may further include, for example, disposing the semiconductor light-emitting device 10A on the package substrate 20A and connecting the first and second electrodes 11a and 12a to the first and second terminals 21 and 22, respectively, before operation S120 is performed. The first and second electrodes 11a and 12a may be electrically connected to the first and second terminals 21 and 22 by using bumps 30a and 30b, for example. The first and second electrodes 11a and 12a may be electrically connected to the first and second terminals 21 and 22 by using wire-bonding W. In addition, the test power may be supplied to the semiconductor light-emitting device 10A via the first and second terminals 21 and 22.

When the test power is supplied, the semiconductor light-emitting device 10A may emit light. The light may be received, and first and second measurements of optical properties of the received light may be performed (S130 and S140) in accordance with principles of inventive concepts. The second measurement may be performed after a predetermined period of time has passed from the first measurement. Next, a process of determining whether the semiconductor light-emitting device 10A is defective or not may be performed by comparing the optical property values obtained in the first and second measurements (S150), in accordance with principles of inventive concepts.

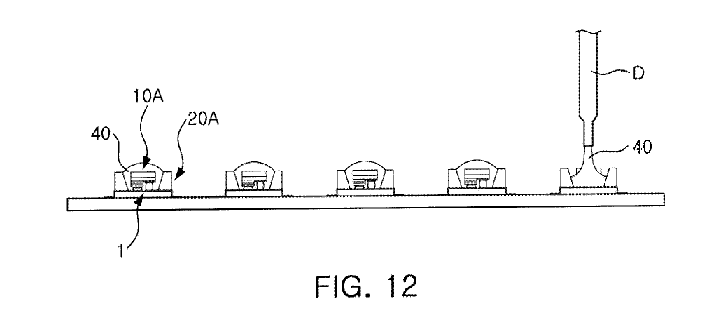

Next, referring to FIG. 12 along with FIG. 11, an encapsulant 40 may be formed on a semiconductor light-emitting device 10A determined as being normal (that is, not defective) after a process of determining whether the semiconductor light-emitting device 10A is defective or not is performed (S160). The encapsulant 40 may cover and encapsulate the semiconductor light-emitting device 10A, and may be formed of a highly transparent resin in order to transmit light generated in the semiconductor light-emitting device 10A with minimal loss. The encapsulant 40 may further include a fluorescent material or a quantum point in order to change a wavelength of light emitted by the semiconductor light-emitting device 10A, for example. The encapsulant 40 may be formed using a variety of methods such as a coating method using a dispenser D.

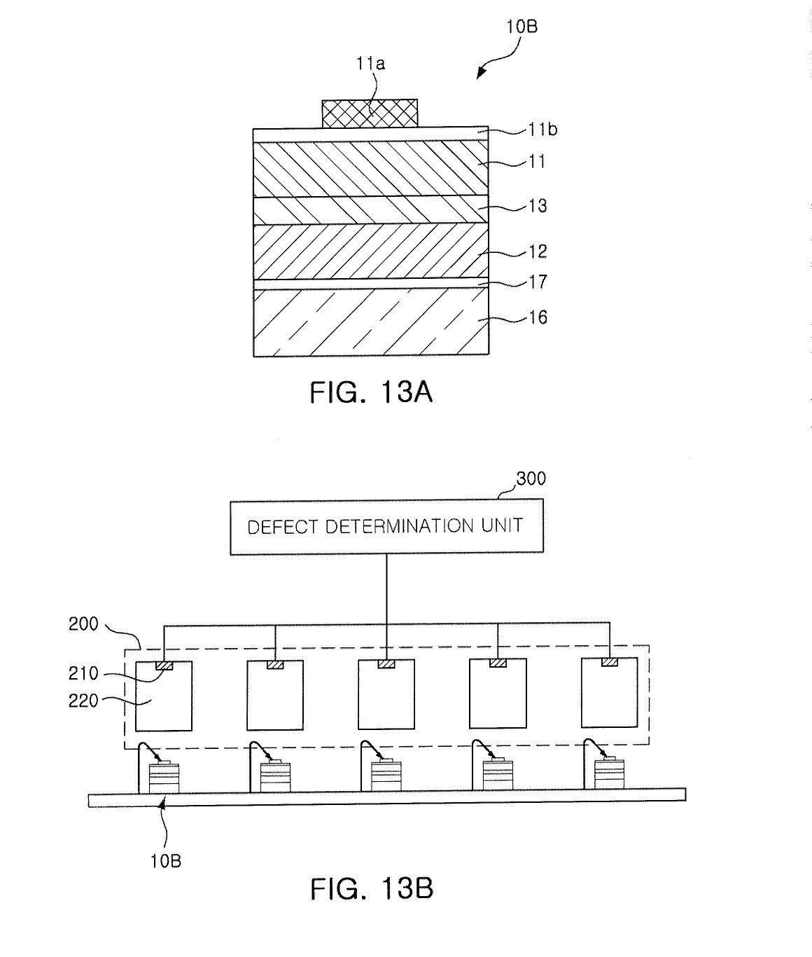

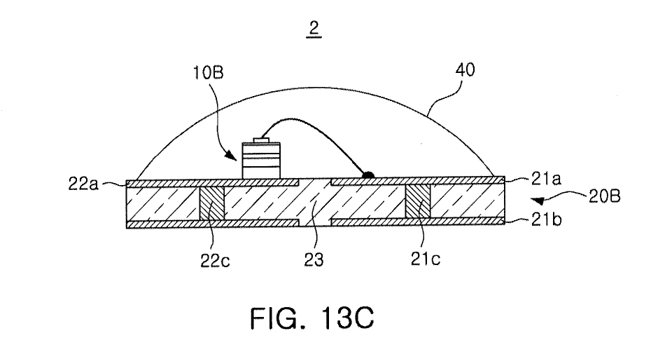

FIGS. 13A to 13C are process cross-sectional views illustrating a method of fabricating a light-emitting device package according to the method described with reference to FIG. 11.

In operation S110 of providing a semiconductor light-emitting device 10B, the light source may be the semiconductor light-emitting device 10B. The semiconductor light-emitting device 10B may include a conductive substrate 16 and a light-emitting structure disposed on the conductive substrate 16. The light-emitting structure may include a second conductivity-type semiconductor layer 12, an active layer 13, and a first conductivity-type semiconductor layer 11. In an embodiment, the first and second conductivity-type may be an n-type or a p-type, respectively. A transparent electrode layer 11b and a first electrode 11a may be formed on the first conductivity-type semiconductor layer 11. The transparent electrode layer 11b may be, for example, a transparent conductive oxide such as Indium Tin Oxide (ITO). The conductive substrate 16 may function as a second electrode 12a applying an electrical signal to the second conductivity-type semiconductor layer 12, and may include one of Au, Ni, Al, Cu, W, Si, Se, and GaAs, for example.

Next, as illustrated in FIG. 13B, test power may be supplied to the semiconductor light-emitting device 10B (S120), and first and second measurements of the optical properties of light emitted by the semiconductor light-emitting device 10B may be performed (S130 and S140). Next, whether the semiconductor light-emitting device 10B is defective or not may be determined by comparing the optical properties obtained in the first and second measurements (S150). In particular, in the semiconductor light-emitting device 10B in accordance with principles of inventive concepts, the conductive substrate 16 may be attached to the second conductivity-type semiconductor layer 12 by the medium of a conductive adhesive layer 17. In an embodiment, whether the bonding is defective or not may be tested through the above-described steps S120 to S150.

Next, as illustrated in FIG. 13C, an encapsulant 40 may be formed on the semiconductor light-emitting device 10B determined as being normal and thus a light-emitting device package 2 may be fabricated. A package substrate 20B illustrated in FIG. 13C may include first and second terminals 21 and 22. The first and second terminals 21 and 22 may respectively include upper pads 21a and 22a, lower pads 21b and 22b, and through-vias 21c and 22c passing through the package body 23 to electrically connect the upper pads 21a and 22a to the lower pads 21b and 22b.

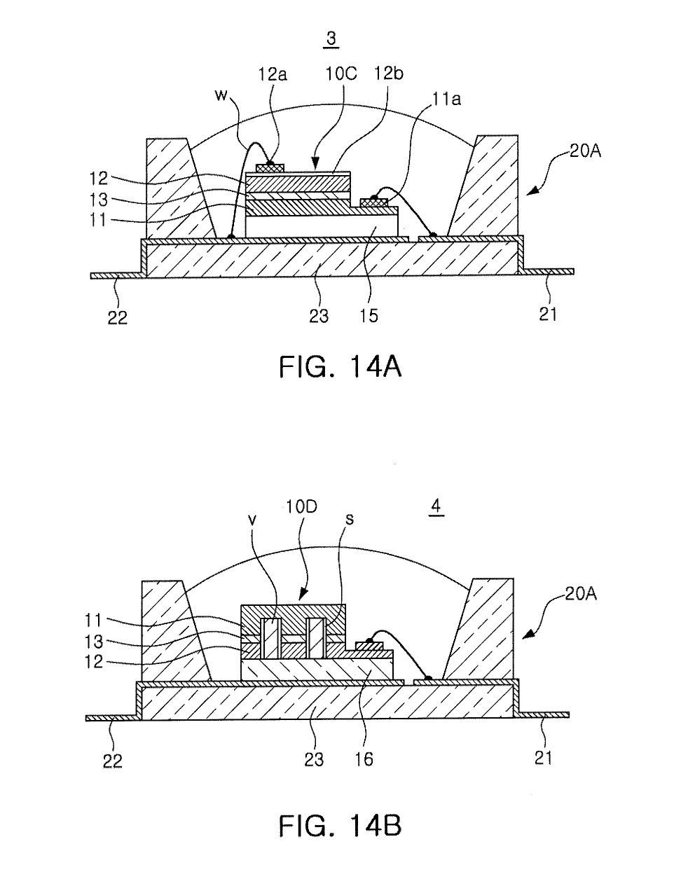

FIGS. 14A and 14B are diagrams exemplarily illustrating light-emitting device packages 3 and 4 fabricated via the method of FIG. 11.

The light-emitting device package 3 illustrated in FIG. 14A may include a semiconductor light-emitting device 10C and a package substrate 20A. The package substrate 20A may include a package body 23 and first and second terminals 21 and 22. The semiconductor light-emitting device 10C may include a substrate 15 and light-emitting structure disposed on the substrate 15 and having first and second electrodes 11a and 12a. The light-emitting structure may include first and second conductivity-type semiconductor layers 11 and 12 and an active layer 13 disposed therebetween. A transparent electrode layer 12b may be formed between the second conductivity-type semiconductor layer 12 and the second electrode 12a. In the light-emitting device package 3 in accordance with principles of inventive concepts, unlike the light-emitting device package 1 illustrated in FIG. 2, the first and second electrodes 11a and 12a may be disposed not to face the first and second terminals 21 and 22, and may be electrically connected through wire-bonding w.

A semiconductor light-emitting device 10D included in a light-emitting device package 4 illustrated in FIG. 14B may include a conductive substrate 16 and a light-emitting structure disposed on the conductive substrate 16. The light-emitting structure may include a first conductivity-type semiconductor layer 11, an active layer 13, and a second conductivity-type semiconductor layer 12. In this embodiment, a conductive via passing through the second conductivity-type semiconductor layer 12 and the active layer 13 to be connected to the first conductivity-type semiconductor layer 11 may be included. An insulating part s may be formed on a side surface of the conductive via v in order to prevent undesired electrical short circuits, for example.

The conductive via v may be electrically connected to the conductive substrate 16, and, accordingly, the conductive substrate 16 may function as a first electrode 11a. A second electrode 12a may be disposed on the second conductivity-type semiconductor layer 12. The conductive via v may be electrically connected to a first terminal 21, and the second electrode 12a may be electrically connected to a second terminal 22. In such an embodiment, a more uniform current may be provided to the light-emitting structure, using the conductive via v.

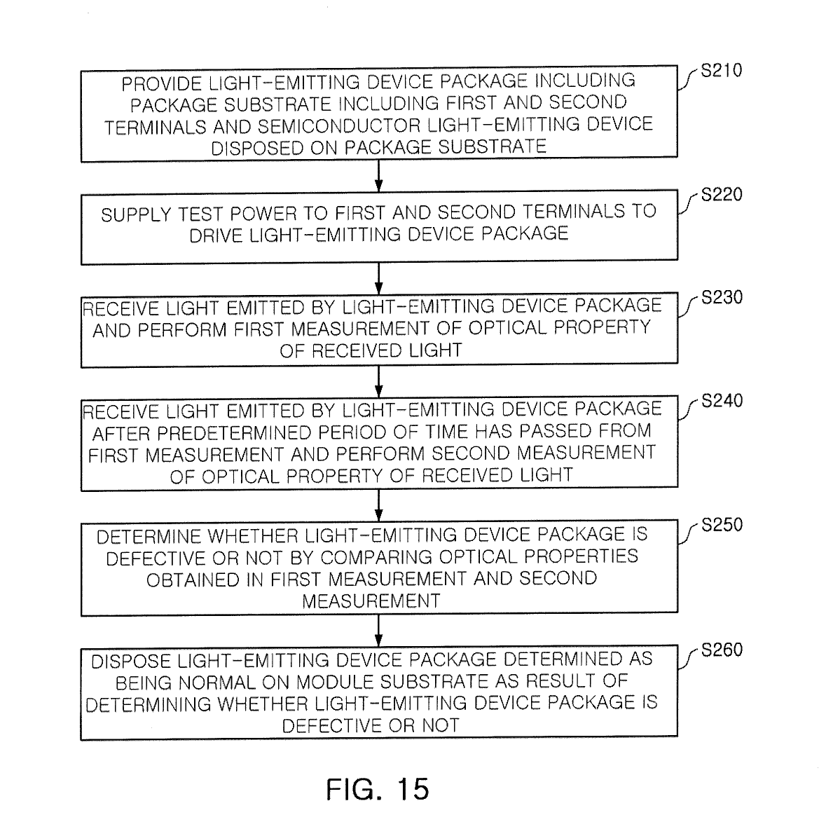

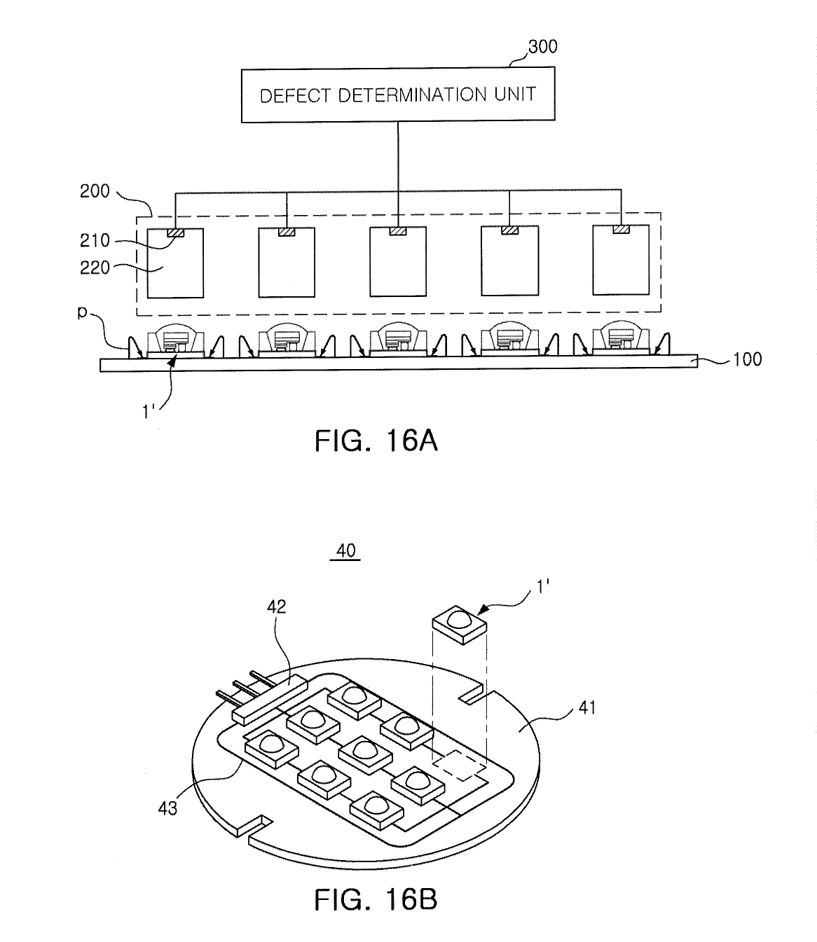

FIG. 15 is a flowchart illustrating a method of fabricating a light-emitting module in accordance with principles of inventive concepts. FIGS. 16A and 16B are process cross-sectional views illustrating the method of fabricating a light-emitting module according to the embodiment of FIG. 15.

Referring to FIG. 16A along with FIG. 15, a method of fabricating a light-emitting module in accordance with principles of inventive concepts includes providing a light-emitting device package 1′ (S210). The light-emitting device package 1′ may include a package substrate having first and second terminals 21 and 22 and a semiconductor light-emitting device disposed on the package substrate. The light-emitting device package 1′ may further include an encapsulant 40 encapsulating the semiconductor light-emitting device.

Next, the method may include providing test power for driving the light-emitting device package 1′ to the first and second terminal (S220). Accordingly, the light-emitting device package 1′ may emit light. Next, the method may include receiving the light emitted by the light-emitting device package 1′ and performing first and second measurements of optical properties of the received light (S230 and S240). The second measurement may be performed after a predetermined period of time has passed from the first measurement.

Next, an example method in accordance with principles of inventive concepts may include determining whether the light-emitting device package 1′ is defective or not by comparing the optical properties obtained in the first and second measurements (S250), as previously described.

Next, referring to FIG. 16B along with FIG. 15, an example method may include disposing the light-emitting device package 1′ determined as being normal as a result of determining whether the light-emitting device package 1′ is defective or not on a module substrate 41 (S260). Thus, a light-emitting module 40 may be fabricated.

In embodiments in accordance with principles of inventive concepts, module substrate 41 may be a circuit board commonly used in the art, for example, a printed circuit board (PCB), a metal core printed circuit board (MCPCB), a metal printed circuit board (MPCB), a flexible printed circuit board (FPCB), for example. The module substrate 41 may include interconnection patterns 43 on a surface and interior thereof, and the interconnection pattern 43 may be electrically connected to the light-emitting device package 1′. The module substrate 41 may include one or more connectors 42 for delivering electrical signals with the outside.

Accordingly, the method of fabricating a light-emitting module with high reliability may be provided.

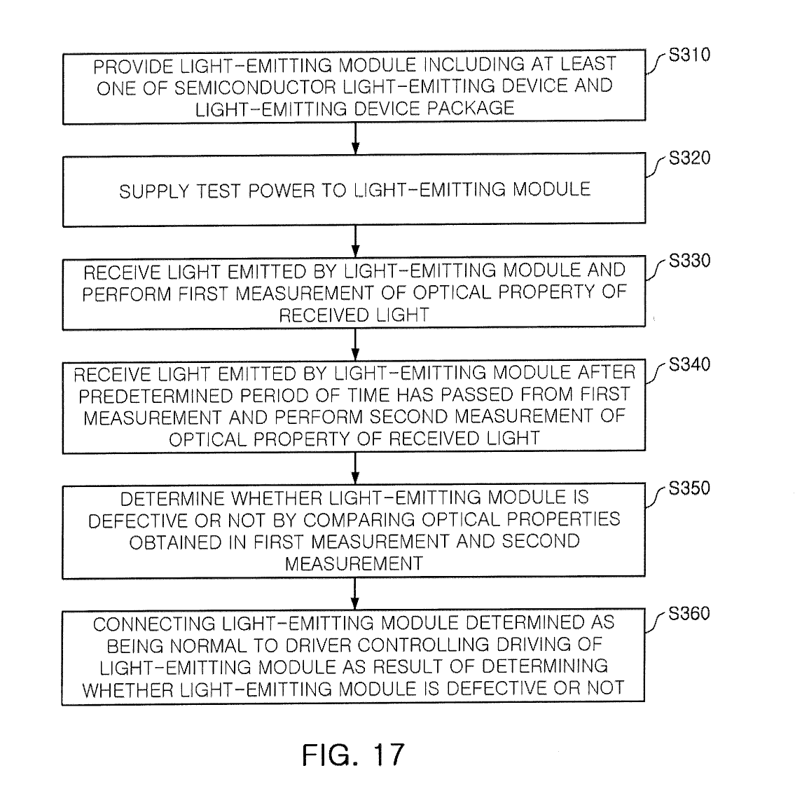

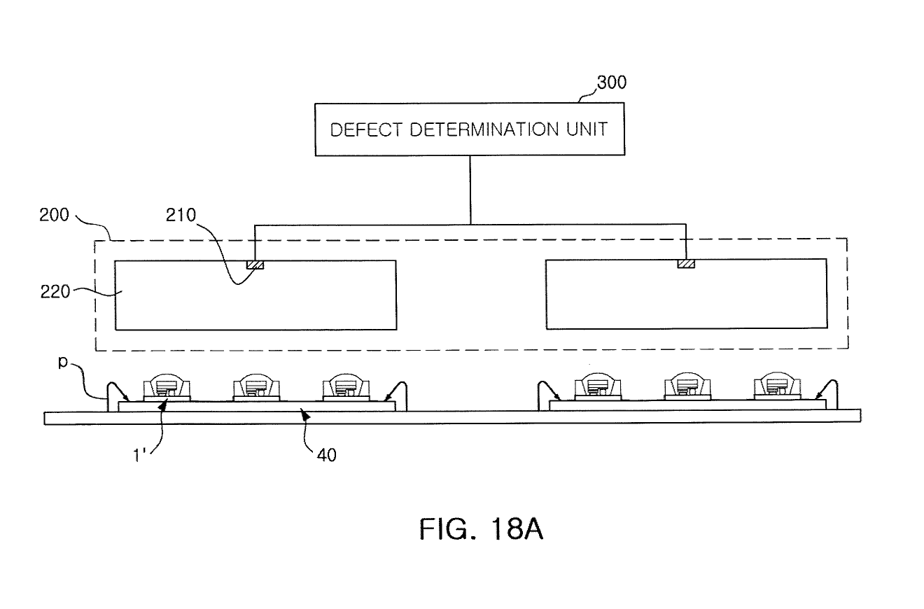

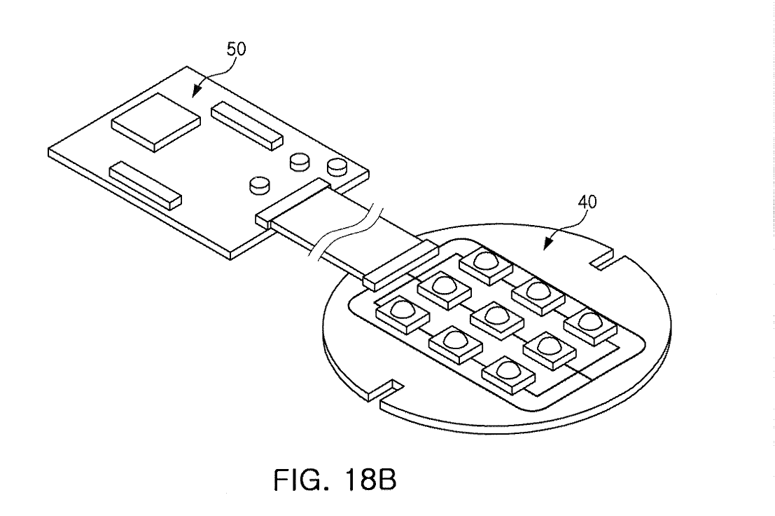

FIG. 17 is a flowchart illustrating a method of fabricating an illumination apparatus in accordance with principles of inventive concepts. FIGS. 18A and 18B are process cross-sectional views illustrating the method of fabricating an illumination apparatus according to the embodiment of FIG. 17.

Referring to FIG. 17, an method of fabricating an illumination apparatus in accordance with principles of inventive concepts may include providing a light-emitting module (S310). The light-emitting module 40 may include a module substrate 41 and at least one of a semiconductor light-emitting device and light-emitting device package disposed on the module substrate 41.

Next, referring to FIG. 18A along with FIG. 17, the method may include supplying test power to the light-emitting module 40 (S320). As a result, the light-emitting module 40 may emit light, and then the method may include receiving the light emitted by the light-emitting module 40 and performing first and second measurements of optical properties of the received light (S330 and S340). The second measurement may be performed after a predetermined period of time has passed from the first measurement.

In this embodiment, the predetermined time may be, for example, about 0.5 sec or less. More specifically, the light-emitting module 40 may be determined as being defective if the amount of change in the luminance level between the first measurement and the second measurement may be equal to or greater than 5%, based on a luminance level obtained in the first measurement, wherein a time interval between the first measurement and the second measurement is about 0.5 sec or less. Alternatively, the light-emitting module 40 may be determined as being defective if an X color coordinate value obtained in the second measurement changes by 0.001 or more, based on an X color coordinate value obtained in the first measurement, or a Y color coordinate value obtained in the second measurement changes by 0.0006 or more, based on a Y color coordinate value obtained in the first measurement, based on the CIE 1931 color coordinates system, wherein a time interval between the first measurement and the second measurement is 0.5 sec or less.

In embodiments in accordance with principles of inventive concepts, the predetermined time (40 msec) for determining whether the light-emitting device package 1 is defective or not may be longer than the predetermined time (0.5 sec) for determining whether the light-emitting module 40 is defective or not. This is because the light-emitting module 40 relatively easily releases heat generated in the semiconductor light-emitting device through the module substrate 41 or the interconnection pattern 43 and, accordingly, time required for increasing a junction temperature increases.

Next, the method may include determining whether the light-emitting module 40 is defective or not by comparing the optical property values obtained in the first and second measurements (S350). It may be understood that whether the light-emitting module 40 is defective or not may be determined using the above-described light source testing method.

Next, referring to FIG. 18B along with FIG. 17, the method may include connecting a driver 50 to the light-emitting module 40 determined as being normal as a result of determining whether the light-emitting module 40 is defective or not (S360). In this manner, the illumination apparatus may be fabricated. The driver 50 may control driving of the light-emitting module 40 and include, for example, an AC/DC converter, a DC/DC converter, or the like.

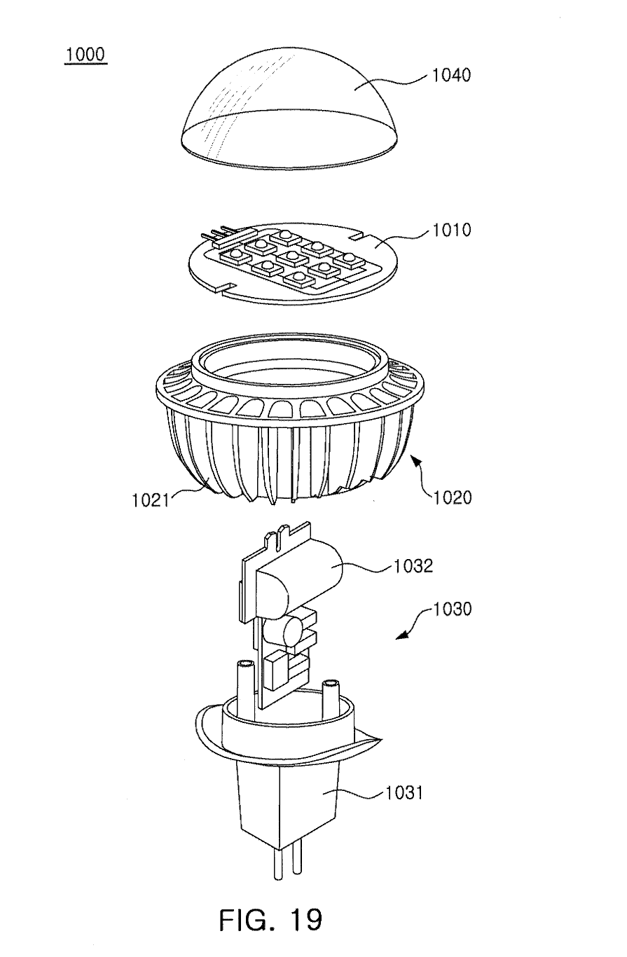

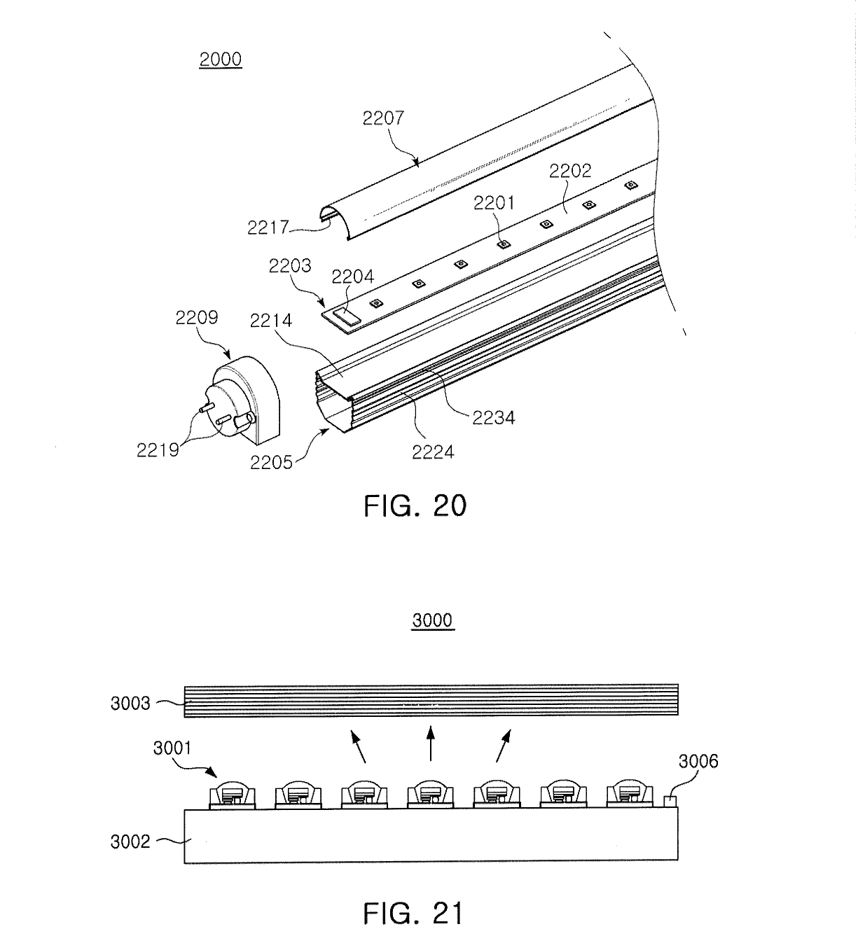

FIGS. 19 and 20 are exploded perspective views schematically illustrating illumination apparatuses fabricated according to embodiments in accordance with principles of inventive concepts.

Referring to FIG. 19, an illumination apparatus 1000 in accordance with principles of inventive concepts may be a bulb-type lamp, and may be used as an indoor lighting device, for example, a downlight. The illumination apparatus 1000 may include a housing 1020 having a driver 1030, and at least one light-emitting module 1010 mounted on the housing 1020, for example. The illumination apparatus 1000 may further include a cover 1040 mounted on the housing 1020 and covering the at least one light-emitting module 1010.

The housing 1020 may function as a frame supporting the light-emitting module 1010, and a heat sink emitting heat generated in the light-emitting module 1010 to the outside. For this purpose, the housing 1020 may be formed of a rigid material having a high degree of thermal conductivity, for example, a metal material such as Al, a heat-dissipating resin, or the like.

In accordance with principles of inventive concepts, a plurality of heat-dissipating fins 1021 for increasing a contact area with surrounding air to improve heat-dissipating efficiency may be formed on an outer side surface of the housing 1020.

The driver 1030 electrically connected to the light-emitting module 1010 may be formed on the housing 1020. The driver 1030 may include a connector 1031 connected to a connecting part of the light-emitting module 1010 to transmit driving power thereto, and a driving power supply 1032 supplying driving power to the light-emitting module 1010 through the connector 1031.

The connector 1031 may install the illumination apparatus 1000 in a socket, for example, to be fixed and electrically connected. In this embodiment, the connector 1031 is described as having a pin-type structure inserted by sliding, but is not limited thereto. In embodiments, the connector 1031 may have an Edison-type structure inserted by turning a screw thread, for example.

The driving power supply 1032 may function to convert external driving power into an appropriate current source for driving the light-emitting module 1010 and supply the converted current source to the light-emitting module 1010. Such a driving power supply 1032 may include, for example, an AC-DC converter, parts for a rectifier circuit, and a fuse. In addition, the driving power supply 1032 may further include a communications module implementing a remote control function, for example.

The cover 1040 may be installed in the housing 1020 to cover the at least one light-emitting module 1010, and may have a convex lens shape or a bulb shape. The cover 1040 may be formed of a light-transmitting material, and include a light-spreading material.

Referring to the exploded perspective view of FIG. 20, an illumination apparatus 2000 may include a light-emitting module 2203, a body 2205, a terminal 2209, and a cover 2207 covering the light-emitting module 2203.

The light-emitting module 2203 may include a module substrate 2202, a plurality of light-emitting device packages 2201 mounted on the module substrate 2202, and a driver 2204 for driving the plurality of light-emitting device packages 2201.

The body 2205 may mount and fix the light-emitting module 2203 on a surface thereof. The body 2205 may be a kind of a supporting structure and include a heat sink. The body 2205 may be formed of a material having a high thermal conductivity, for example, a metal material, in order to release heat generated in the light-emitting module 2203 to the outside, but is not limited thereto.

The body 2205 may be of an elongated rod shape overall, corresponding to a shape of the module substrate 2202 of the light-emitting module 2203. A recess 2214 capable of accommodating the light-emitting module 2203 may be formed on the surface on which the light-emitting module 2203 is mounted.

A plurality of heat dissipating fins 2224 for heat dissipation may be formed to protrude on both outer side surfaces of the body 2205. In addition, fastening grooves 2234 extending in a longitudinal direction of the body 2205 may be formed on both ends of the outer side surface disposed on the recess 2214. The cover 2207, which will be described in greater detail later, may be fastened to the fastening grooves 2234.

Both ends of the body 2205 in a longitudinal direction may be open such that the body 2205 has a pipe structure in which both ends thereof are open. In this embodiment, both ends of the body 2205 are described as being open, but embodiments are not limited thereto. For example, only one end of the body 2205 may be open.

The terminal 2209 may be disposed on at least one open end of both ends of the body 2205 in the longitudinal direction to supply power to the light-emitting module 2203. In this embodiment, both ends of the body 2205 are open and the terminal 2209 is disposed on each end of the body 2205. However, inventive concepts are not limited thereto. For example, in a structure in which only one end of the body 2205 is open, the terminal 2209 may be disposed on the one open end of the body 2205.

The terminal 2209 may be connected to both open ends of the body 2205 to cover the open ends. The terminal 2209 may further include an electrode pin 2019 protruding outside.

The cover 2207 may be combined with the body 2205 to cover the light-emitting module 2203. The cover 2207 may be formed of a light-transmitting material.

The cover 2207 may have a semi-circularly curved surface (parabolic, for example) so that light is uniformly emitted to the outside overall. In addition, an overhang 2217 engaged with the fastening groove 2234 of the body 2205 may be formed at a bottom of the cover 2207 combined with the body 2205 in a longitudinal direction of the cover 2207.

In this embodiment, the cover 2207 is illustrated as having a semi-circular shaped structure, but embodiments are not limited thereto. For example, the cover 2207 may have a flat rectangular structure or another polygonal structure. The shape of the cover 2207 may be variously modified depending on a design of an illumination apparatus which emits light.

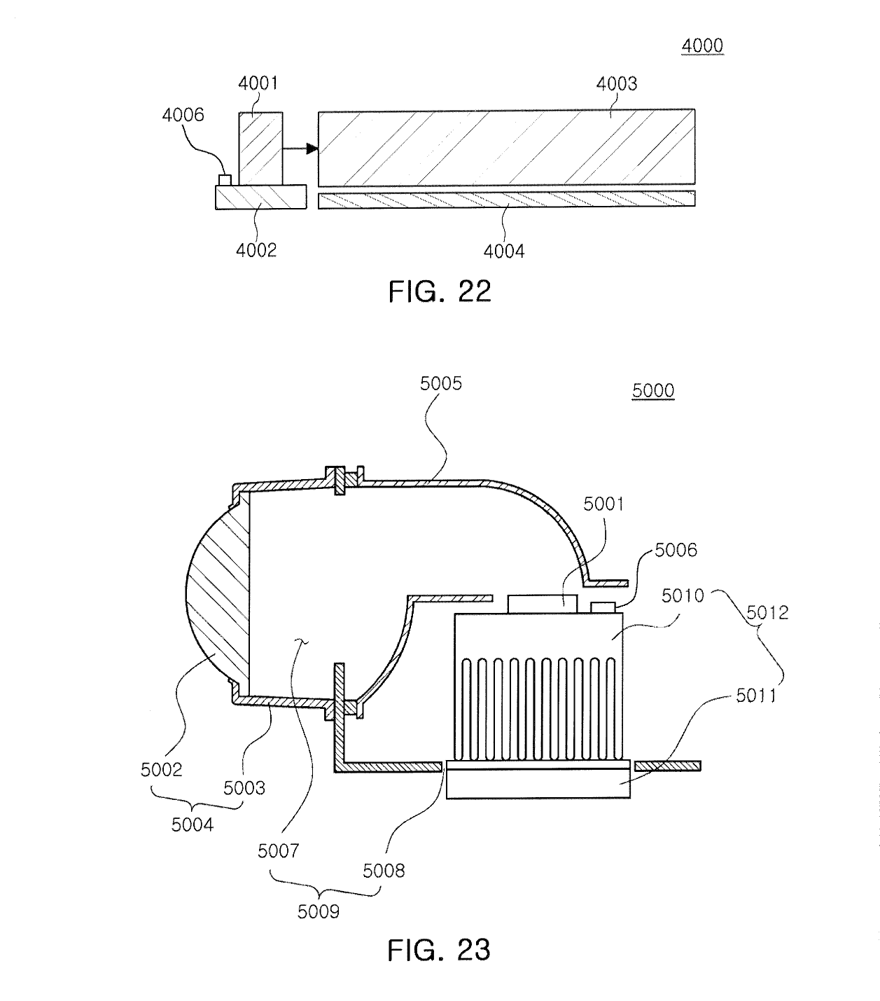

FIGS. 21 and 22 are cross-sectional views illustrating examples in which an illumination apparatus fabricated in accordance with principles of inventive concepts is applied to a backlight unit.

Referring to FIG. 21, a backlight unit 3000 may include a light-emitting module 3001 in accordance with principles of inventive concepts mounted on a module substrate 3002, and one or more optical sheets 3003 disposed on the light-emitting module 3001. The backlight unit 3000 may further include a driver 3006 for driving the light-emitting module 3001.

The light-emitting module 3001 in the backlight unit 3000 illustrated in FIG. 21 emits light toward a top surface (top of optical sheets 3003, for example) where a liquid crystal display (LCD) is disposed. In another backlight unit 4000 illustrated in FIG. 22, a light-emitting module 4001 mounted on a module substrate 4002 emits light in a lateral direction, and the emitted light may be incident to a light guide plate 4003 and converted to the form of surface light. Light passing through the light guide plate 4003 is emitted upwardly, and a reflective layer 4004 may be disposed on a bottom surface of the light guide plate 4003 to improve light extraction efficiency. The backlight unit 4000 may further include a driver 4006 supplying driving power to the light-emitting module 4001 in accordance with principles of inventive concepts.

FIG. 23 is a cross-sectional view illustrating an embodiment in which an illumination apparatus fabricated in accordance with principles of inventive concepts is applied to a headlamp.

Referring to FIG. 23, a headlamp 5000 used as a vehicle lamp, for example, may include a light-emitting module 5001 in accordance with principles of inventive concepts, a reflective unit 5005, and a lens cover unit 5004. The lens cover unit 5004 may include a hollow-type guide 5003 and a lens 5002. Additionally, the headlamp 5000 may further include a heat dissipation unit 5012 dissipating heat generated by the light-emitting module 5001 outwardly. In order to effectively dissipate heat, the heat dissipation unit 5012 may include a heat sink 5010 and a cooling fan 5011. In addition, the headlamp 5000 may further include a housing 5009 fixedly supporting the heat dissipation unit 5012 and the reflective unit 5005, and the housing 5009 may have a central hole 5008 formed in one surface thereof, to which the heat dissipation unit 5012 is coupledly installed. Further, the housing 5009 may have a front hole 5007 formed on the other surface integrally connected to the one surface and bent in a right angle direction. The front hole 5007 may fix the reflective unit 5005 to be disposed over the light-emitting module 5001. As a result, a front side of the housing 5009 may be open by the reflective unit 5005. The reflective unit 5005 is fixed to the housing 5009 such that the opened front side corresponds to the front hole 5007, and thereby light reflected by the reflective unit 5005 may pass through the front hole 5007 to be emitted outwardly. The headlamp 5000 may further include a driver 5006 for driving the light-emitting module 5001.

As set forth above, a light source testing apparatus according to embodiments may be easily implemented and serve to effectively detect even a fine defect and may improve the accuracy of testing. embodiment According to the embodiments, a highly reliable method of fabricating a light-emitting device package, a light-emitting module, and an illumination apparatus may be obtained.

While embodiments have been shown and described above, it will be apparent to those skilled in the art that modifications and variations could be made without departing from the spirit and scope of inventive concepts, as defined by the appended claims.

1. A method of fabricating a light source, comprising:
providing a semiconductor light source emitting light when power is applied thereto;
supplying power to the semiconductor light source;
receiving light emitted by the semiconductor light source and performing a first measurement of optical properties of the received light;
receiving light emitted by the semiconductor light source after a period of time has elapsed from the first measurement and performing a second measurement of optical properties of the received light;
determining whether the semiconductor light source is defective or not by comparing the results of the first measurements of optical properties and the second measurements of optical properties; and
constructing the light source including the semiconductor light source by providing peripheral parts thereof, wherein the semiconductor light source is determined as being normal as a result of determining whether the semiconductor light source is defective or not.

2. The method of claim 1, wherein the determining of whether the semiconductor light source is defective or not comprises:
determining an amount of change in the optical property between the first and second measurements, based on the optical property obtained in the first measurement; and
determining the semiconductor light source as being defective if the calculated amount of change is equal to or greater than a predetermined value.

3. The method of claim 2, wherein the optical properties obtained in the first and second measurements are luminance levels of light emitted by the semiconductor light source.

4. The method of claim 3, wherein the optical properties are obtained using a photodiode.

5. The method of claim 2, wherein the optical properties obtained in the first and second measurements comprise color coordinate values of light emitted by the semiconductor light source.

6. The method of claim 5, wherein the optical properties are obtained using a spectrometer.

7. The method of claim 1, wherein the performing of the first and second measurements includes obtaining first and second images by imaging the light emitted by the semiconductor light source, and
the determining of whether the semiconductor light source is defective or not comprises comparing brightness levels of the first and second images and determining the semiconductor light source as being defective if the amount of change in the brightness level is equal to or greater than a predetermined value.

8. The method of claim 7, wherein a plurality of semiconductor light sources are tested, and the determining of whether the plurality of semiconductor light sources are defective or not comprises:
setting segmentation regions corresponding to locations of the plurality of semiconductor light sources on each of the first and second images; and
comparing the brightness levels of the first and second images for each of the segmentation regions and determining the semiconductor light source located in a location corresponding to the segmentation region as being defective if the amount of change in the brightness level is equal to or greater than a predetermined value.

9. The method of claim 1, wherein:
the light source is a light-emitting module;
the semiconductor light source is a light-emitting device package including a package substrate having first and second terminals and a semiconductor light-emitting device on the package substrate and having first and second electrodes electrically connected to the first and second terminals; and
the constructing of the light source comprises disposing the light-emitting device package determined as being normal as a result of determining whether the light-emitting device package is defective or not, on a module substrate.

10. The method of claim 9, wherein the first and second electrodes of the semiconductor light-emitting device are positioned to face the first and second terminals of the package substrate.

11. The method of claim 9, wherein the optical properties obtained in the first and second measurements are luminance levels of light emitted by the light-emitting device package,
a time interval between the first measurement and the second measurement is 40 msec or less, and
the light-emitting device package is determined as being defective if the amount of change in the luminance level between the first measurement and the second measurement is 5% or more, based on a luminance level obtained in the first measurement.

12. The method of claim 9, wherein the optical properties obtained in the first and second measurements are color coordinate values of light emitted by the light-emitting device package,
a time interval between the first measurement and the second measurement is 40 msec or less, and
the light-emitting device package is determined as being defective if an X color coordinate value obtained in the second measurement changes by 0.001 or more, based on an X color coordinate value obtained in the first measurement, or a Y color coordinate value obtained in the second measurement changes by 0.0006 or more, based on a Y color coordinate value obtained in the first measurement, based on the CIE 1931 color coordinates system.

13. The method of claim 1, wherein the semiconductor light source is a semiconductor light-emitting device including a conductive substrate and a light-emitting structure on the conductive substrate and having a first conductivity-type semiconductor layer, an active layer, and a second conductivity-type semiconductor layer.

14. The method of claim 1, wherein:
the light source is an illumination apparatus;
the semiconductor light source is a light-emitting module including a module substrate and at least one of semiconductor light-emitting device and light-emitting device package on the module substrate; and
the constructing of the light source comprises connecting a driver configured to control driving of the light-emitting module to the light-emitting module determined as being normal as a result of determining whether the light-emitting module is defective or not.

15. The method of claim 14, wherein the optical properties obtained in the first and second measurements are luminance levels of light emitted by the light-emitting module,
a time interval between the first measurement and the second measurement is 0.5 sec or less, and
the light-emitting module is determined as being defective if an amount of change in the luminance level between the first measurement and the second measurement is 5% or more, based on a luminance level obtained in the first measurement.

16. The method of claim 14, wherein the optical properties obtained in the first and second measurements are color coordinate values of light emitted by the light-emitting module,
a time interval between the first measurement and the second measurement is 0.5 sec or less, and
the light-emitting module is determined as being defective if an X color coordinate value obtained in the second measurement changes by 0.001 or more, based on an X color coordinate value obtained in the first measurement, or a Y color coordinate value obtained in the second measurement changes by 0.0006 or more, based on a Y color coordinate value obtained in the first measurement, based on the CIE 1931 color coordinates system.

17. The method of claim 1, wherein a plurality of semiconductor light sources are tested, and
the performing of the first and second measurements includes receiving light emitted by each of the plurality of semiconductor light sources and performing the first and second measurements of the optical properties of the received light.

18. The method of claim 17, further comprising storing a result of determining whether each of the plurality of semiconductor light sources is defective or not, in a memory device.

19. The method of claim 1, wherein:
the light source is a light-emitting device package;
the semiconductor light source is a semiconductor light-emitting device having first and second electrode structures and a package substrate having first and second terminals; and
the constructing of the light source comprises forming an encapsulant on the semiconductor light-emitting device determined as being normal as a result of determining whether the semiconductor light-emitting device is defective or not.

20.-45. (canceled)
